(19) United States
(12) Patent Application Publication
(10) Pub. No.: US 2012/0211739 A1
(43) Pub. Date: Aug. 23, 2012

(54) ORGANIC ELECTRONIC DEVICE

(75) Inventors: Hirokazu Koyama, Tokyo (JP); Takatoshi Suematsu, Tokyo (JP)

(73) Assignee: KONICA MINOLTA HOLDINGS, INC., Tokyo (JP)

(21) Appl. No.: 13/502,979

(22) PCT Filed: Oct. 21, 2010
(86) PCT No.: PCT/JP2010/068569

§ 371 Date: Apr. 19, 2012

(30) Foreign Application Priority Data
Oct. 28, 2009 (JP) JP2009-247589

(51) Int. Cl. H01L 51/46; H01L 51/54

(52) U.S. Cl. 257/40; 257/E51.026

(57) ABSTRACT

The organic electronic device prevents short-circuiting between electrodes and improves lifetime without deteriorating transmittance, driving voltage stability and storage stability thereof. The organic electronic device has a substrate and provided thereon, a first electrode and a second electrode opposed to each other and at least one organic functional layer located between the first and second electrodes. At least one of the first and second electrodes has an electrically conductive polymer-containing layer containing a hydrophilic polymer binder and an electrically conductive polymer having a π conjugated electrically conductive polymer component and a polyanion component. At least a part of the electrically conductive polymer-containing layer is subjected to crosslinking, and the electrically conductive polymer-containing layer has been subjected to wet washing treatment.

### FIELD OF THE INVENTION

The present invention relates to an organic electronic device having a multilayered structure, and particularly to an organic electronic device which prevents short-circuiting between electrodes and improves the device lifetime without deteriorating transmittance, driving voltage stability and storage stability.

### TECHNICAL BACKGROUND

An electrically conductive polymer comprised of a π conjugated electrically conductive polymer component and a polyanion component is used as an antistatic agent, or as a hole ejection material or a hole transport material in a part of various electrodes in an organic EL Element or an organic solar cell.

An organic electronic device such as an organic EL Element or an organic solar cell comprises functional layers with a thickness of approximately 100 nm. Therefore, if the electrodes in the device have on the surface protrusions exceeding several tens nm, leakage between the electrodes occurs and even if the leakage does not occur, an electric field is accumulated on the portions where the protrusions are located, resulting in occurrence of dark spots or in deterioration of lifetime.

In organic electronic device such as an organic EL Element or an organic solar cell, there are many cases where a layer of a π conjugated electrically conductive polymer as a hole injection material or a hole transport material is laminated on the electrode ITO or ZnO in which protrusions and recesses on the surface are controlled.

It is known that wet washing treatment or a dry washing treatment such as UV ozone treatment is carried out as a method for removing foreign matter present on the surface of an inorganic electrically conductive layer such as ITO.

However, occurrence of troubles due to irregular protrusions or foreign matter on the surface of the electrode is not sufficiently prevented. Further, troubles due to foreign matter during and after formation of auxiliary electrodes occur.

As an approach for solving the problems as above-described regarding smoothness of the electrode surface, it is considered that the irregular protrusions or foreign matter are buried in an electrically conductive polymer-containing layer with an increased thickness (see, for example, Patent Document 1). However, the electrically conductive polymer ordinarily has absorption in the visible wavelength region, and therefore, the increased thickness of the layer results in deterioration of light transmittance.

Patent Document 1 discloses a hole injection layer containing a non-aqueous intrinsic electrically conductive polymer, dopant or a synthetic polymer leveling agent. However, it has been found that such a hole injection layer extremely increases driving voltage, as compared with a hole injection layer containing no synthetic polymer leveling agent. Although this is not clear, it is considered that the synthetic polymer has a surface energy close to that of the intrinsic electrically conductive polymer or dopant, and therefore, the synthetic polymer in a large amount orients on the layer surface to form an insulation portion there.

With respect to antistatic technique, an antistatic layer is disclosed in Patent Document 3 which contains (i) an electrically conductive polymer which composed of a polythiophene-based polymer and a polyanion, and which is soluble or dispersible in an aqueous solvent and (ii) a binder resin soluble or dispersible in an aqueous solvent. When this technique is applied, for example, to an electrically conductive polymer-containing layer of an organic EL Element, it has been found that driving voltage increases and storage property deteriorates.

With respect to antistatic technique, an antistatic coating solution is disclosed in Patent Document 4 which contains a π conjugated electrically conductive polymer component and a polyanion component, a specific cross-linking point-forming compound and a solvent. This technique has a certain degree of washing resistance owing to the cross-linking point-forming compound. However, it has been found that this technique also increases driving voltage and deteriorates storage property as compared with that employing a coating solution containing no cross-linking point-forming compound. It is presumed that the antistatic coating solution contains a cross-linking point-forming compound (monomer), and when a layer is formed from the solution, the monomer remains in the coating solution so as to contain a larger amount of the monomer in the surface of the layer, so that an insulation portion is formed in the layer.

### PRIOR ART DOCUMENT

### Patent Document

Patent Document 1: Japanese Patent O.P.I. Publication No. 2003-045665

Patent Document 2: Japanese Unexamined Patent Application Publication (Translation of PCT Application) No. 2008-533701

Patent Document 3: Japanese Patent O.P.I. Publication No. 2006-198805

Patent Document 4: Japanese Patent O.P.I. Publication No. 2006-143922

### DISCLOSURE OF THE INVENTION

### Problems to be Solved by the Invention

The present invention has been made in view of the above. An object of the invention is to provide an organic electronic device which prevents short-circuiting between electrodes and improves the device lifetime without deteriorating the transmittance, driving voltage stability and storage stability.

### Means for Solving the Problems

The above object of the invention can be attained by the following constitutions.

1. An organic electronic device comprising a substrate and provided thereon, a first electrode and a second electrode opposed to each other and at least one organic functional layer located between the first and second electrodes, the organic electronic device featured in that at least one of the first and second electrodes comprises an electrically conductive polymer-containing layer containing a hydrophilic polymer binder and an electrically conductive polymer comprised of a π conjugated electrically conductive polymer component and a polyanion component, at least a part of the electrically conductive polymer-containing layer is subjected to crosslinking, and the electrically conductive polymer-containing layer has been subjected to wet washing treatment.

2. The organic electronic device as described in item 1 above, featured in that the wet washing treatment is washing treatment carried out employing an aqueous solvent.

3. The organic electronic device as described in item 1 or 2 above, featured in that the wet washing treatment is washing treatment carried out employing two or more washing tanks which are continuously connected.

4. The organic electronic device as described in any one of items 1 through 3 above, featured in that the wet washing treatment is a multi-stage washing treatment in which overflow is carried out.

5. The organic electronic device as described in any one of items 1 through 4 above, featured in that a carbon atom concentration at a surface of the electrically conductive polymer-containing layer after the wet washing treatment is not less than 3% higher than that before the wet washing treatment.

6. The organic electronic device as described in any one of items 1 through 5 above, featured in that the polyanion component is a polymer having a sulfo group, and the hydrophilic polymer binder has a hydroxyl group in the side chain.

7. The organic electronic device as described in item 6 above, featured in that the hydrophilic polymer binder comprises the following Polymer (A),

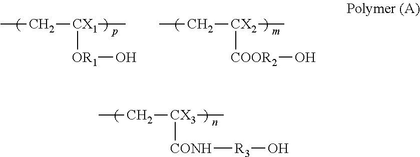

wherein X₁ through X₃ independently represent a hydrogen atom or a methyl group; R₁ through R₃ represent an alkylene group having a carbon atom number of not more than 5; and p, m and n represent a content ratio (by mol %); in which 50≦p+m+n≦100

8. The organic electronic device as described in item 7 above, featured in that the cross-linking of the electrically conductive polymer-containing layer is carried out through dehydration reaction of the hydroxyl group.

### Effects of the Invention

The present invention can provide an organic electronic device which prevents short-circuiting between electrodes and improves the device lifetime without deteriorating the transmittance, driving voltage stability and storage stability.

### BRIEF EXPLANATION OF DRAWINGS

FIG. 1 is a sectional schematic view showing one embodiment of structures of an organic electronic device.

FIG. 2 is a schematic view showing one embodiment of shapes of an auxiliary electrode.

FIG. 3 is a schematic view showing one embodiment of structures of electrode patterns.

### PREFERRED EMBODIMENTS FOR CARRYING OUT THE INVENTION

Next, preferred embodiment for carrying out the invention will be explained in detail, but the invention is not limited thereto.

In the invention, the electrically conductive polymer-containing layer contains a binder to increase the thickness while maintaining high transmittance, whereby foreign matter is buried in the layer to prevent short-circuiting between electrodes and minimize occurrence of dark spots. However, when a binder is used, generally the driving voltage of the device varies, resulting in lowering of efficiency or storage stability, which makes it difficult to use a binder.

Presence of obstacles to charge transfer inside the device produces loss of voltage and lowers efficiency. There is problem in an emission device that increases application voltage necessary to emit a specific luminance and there is problem in a photoelectric conversion device that lowers output voltage.

In the invention, driving voltage in an emission device refers to application voltage necessary to emit a specific luminance and that in a photoelectric conversion device to output voltage obtained when a specific light is incident.

It has been possible to restrain variation of driving voltage to some degree by using a hydrophilic polymer binder as a binder. The reason is not clear. It is considered that when an electrically conductive polymer-containing layer is formed, a hydrophilic polymer having a relatively high surface energy is not oriented on the surface thereof and an electrically conductive polymer having a relatively low surface energy is likely to be oriented on the surface thereof whereby an insulation layer is not formed on the surface and variation of driving voltage is restrained to some degree. The electrically conductive polymer-containing layer, which is at least partially cross-linked, is subjected to wet washing treatment whereby a hydrophilic polymer present on the layer surface or a lower molecular weight component of a hydrophilic polymer or a polyanion, which is dissolved in the solution during drying on account of its high solubility to remain on the layer surface, is removed, resulting in further restraining variation of driving voltage.

It is also considered that a component such as a catalyst residue or a lower molecular weight component, which is likely to move in the layer, is solidified in the layer or removed from the layer by the cross-linking or the wet washing treatment, resulting in improvement of storage stability.

### <<Electrically Conductive Polymer>>

The electrically conductive polymer in the invention is an electrically conductive polymer comprised of a π conjugated electrically conductive polymer component and a polyanion component. Such an electrically conductive polymer can be easily produced by chemical oxidization polymerization of a precursor monomer described later which forms a π conjugated electrically conductive polymer in the presence of a suitable oxidizing agent, an oxidation catalyst and a polyanion described later.

### <<Π Conjugated Electrically Conductive Polymer>>

The π conjugated electrically conductive polymer used in the present invention is not particularly limited. As such a π conjugated electrically conductive polymer, there can be used the following chained conductive polymers such as polythiophenes (including a basic polythiophene, hereinafter the same meaning shall apply.), polypyrroles, polyindoles, polycarbazoles, polyanilines, polyacethylenes, polyfurans, polyparaphenylene vinylelenes, polyazulenes, polyparaphenylenes, polyparaphenylene sulfides, polyisothianaphthenes and polythiazyls. Among them, polythiophenes and polyanilines are preferred from the viewpoints of electrical conductivity, transparency and stability. Polyethylene dioxythiophene is most preferred.

### [Π Conjugated Electrically Conductive Polymer Precursor Monomer]

The precursor monomer is a compound having a π conjugated system in the molecule and forms a π conjugated system also in the main chain of a polymer obtained when it is polymerized by action of a suitable oxidizing agent. Examples thereof include pyrroles or their derivatives, thiophenes or their derivatives, and anilines or their derivative.

Typical examples of the precursor monomer include pyrrole, 3-methylpyrrole, 3-ethylpyrrole, 3-n-propylpyrrole, 3-butylpyrrole, 3-octylpyrrole, 3-decylpyrrole, 3-dodecylpyrrole, 3,4-dimethylpyrrole, 3,4-dibutylpyrrole, 3-carboxyl pyrrole, 3-methyl-4-carboxyl pyrrole, 3-methyl-4-carboxyethyl pyrrole, 3-methyl-4-carboxybutylpyrrole, 3-hydroxypyrrole, 3-methoxypyrrole, 3-ethoxypyrrole, 3-butoxypyrrole, 3-hexyloxypyrrole, 3-methyl-4-hexyloxypyrrole, thiophene, 3-methylthiophene, 3-ethylthiophene, 3-propylthiophene, 3-butylthiophene, 3-hexylthiophene, 3-heptylthiophene, 3-octylthiophene, 3-decylthiophene, 3-dodecylthiophene, 3-octadecylthiophene, 3-bromothiophene, 3-chlorothiophene, 3-iodothiophene, 3-cyanothiophene, 3-phenylthiophene, 3,4-dimethylthiophene, 3,4-dibutylthiophene, 3-hydroxythiophene, 3-methoxythiophene, 3-ethoxythiophene, 3-butoxythiophene, 3-hexyloxythiophene, 3-heptyloxythiophene, 3-octyloxythiophene, 3-decyloxythiophene, 3-dodecyloxythiophene, 3-octadecyloxythiophene, 3,4-dihydroxythiophene and 3,4-dimethoxythiophene, 3,4-diethoxthiophene, 3,4-dipropoxythiophene, 3,4-dibutoxythiophene, 3,4-dihexyloxythiophene, 3,4-diheptyloxythiophene, 3,4-dioctyloxythiophene, 3,4-didecyloxythiophene, 3,4-didodecyloxythiophene, 3,4-ethylenedioxythiophene, 3,4-propylenedioxythiophene, 3,4-butenedioxythiophene, 3-methyl-4-methoxythiophene, 3-methyl-4-ethoxythiophene, 3-carboxythiophene, 3-methyl-4-carboxythiophene, 3-methyl-4-carboxyethyl thiophene, 3-methyl-4-carboxybutylthiophene, aniline, 2-methylaniline, 3-isobutylaniline, 2-anilinesulfonic acid, and 3-anilinesulfonic acid.

### <<Polyanion>>

The polyanion is a substituted or unsubstituted polyalkylene, a substituted or unsubstituted polyalkenylene, a substituted or unsubstituted polyimide, a substituted or unsubstituted polyamide, a substituted or unsubstituted polyester or a copolymer thereof, and is composed of a structural unit with an anionic group and a structural unit without an anionic group.

This polyanion is a solubilizing polymer which causes a π conjugated electrically conductive polymer to dissolve in a solvent. Moreover, the anionic group of the polyanion functions as a dopant to the π conjugated electrically conductive polymer, and improves conductivity and heat resistance of the π conjugated electrically conductive polymer.

The anionic group of the polyanion may be a functional group which can carry out chemical oxidation dope to the π conjugated electrically conductive polymer. A monosubstituted sulfate group, a monosubstituted phosphate group, a phosphate group, a carboxyl group and a sulfo group are especially preferred in view of stability and ease of productivity. Further, a sulfo group, a monosubstituted sulfate group and a carboxyl group are more preferred in view of the doping effect of a functional group to the π electrically conjugated conductive polymer.

Typical examples of the polyanion include polyvinyl sulfonic acid, polystyrene sulfonic acid, polyallyl sulfonic acid, polyethylacrylate sulfonic acid, polybutylacrylate sulfonic acid, poly-2-acrylamide-2-methylpropane sulfonic acid, polyisoprene sulfonic acid, polyvinyl carboxylic acid, polystyrene carboxylic acid, polyallyl carboxylic acid, polyacryl carboxylic acid, polymethacryl carboxylic acid, poly-2-acrylamide-2-methylpropane carboxylic acid, polyisoprene carboxylic acid and polyacrylic acid. These may be homopolymers or copolymers comprised of two or more kinds thereof.

It may be a polyanion containing a fluorine atom in the molecule. Typical examples include Nafion™ containing a perfluorosulfonic acid (produced by DuPont Co., Ltd.) and Flemion™ composed of a perfluoro vinyl ether containing a carboxylic acid group (produced by Asahi Glass Co., Ltd.).

Among these, the compound containing a sulfonic acid is preferred, since when an electrically conductive polymer-containing layer formed after coating and drying is subjected to heat-treatment for 5 minutes or more at a temperature of 100° C. to 200° C., cleaning resistance and solvent resistance of this coated layer is markedly improved.

Further, among these, polystyrene sulfonic acid, polyisoprene sulfonic acid, polyethylacrylate sulfonic acid, and polybutylacrylate sulfonic acid are preferred. These polyanions have high compatibility with the binder resin, and can provide higher electrical conductivity to the electrically conductive polymer obtained therefrom.

The degree of polymerization of the polyanion is preferably in the range of from 10 to 100,000 and more preferably in the range of 50 to 100,000 in terms of the monomer units from the viewpoint of solvent solubility and electrical conductivity.

As a production method of a polyanion, there are, for example, a method in which an anion group is directly introduced into a polymer containing no anion group, using an acid; a method in which sulfonation of a polymer containing no anion group is carried out, using a sulfonating agent; and a method in which polymerization is carried out using a polymerizable monomer containing an anion group.

With respect to a production method in which polymerization is carried out using a polymerizable monomer containing an anion group, there is, for example, the following method. A polymerizable monomer containing an anion group is subjected to an oxidation polymerization or a radical polymerization in the presence of an oxidizing agent and/or a polymerization catalyst in a solvent. Specifically, a predetermined amount of a polymerizable monomer containing an anion group is dissolved in a solvent and kept at a constant temperature. A solution, in which a predetermined amount of oxidizing agent and/or polymerization catalyst is dissolved in a solvent beforehand, is added to the resulting mixture and reacted for a predetermined time. The resulting polymer solution is adjusted to a specific concentration by a solvent. In this production method, copolymerization can be carried out of a polymerizable monomer containing no anion group with a polymerizable monomer containing an anion group.

An oxidizing agent, an oxidation catalyst and a solvent used in polymerization of a polymerizable monomer containing an anion group are the same as used in polymerization of a precursor monomer to form a π conjugated electrically conductive polymer.

When the obtained polymer is a polyanion salt, it is preferably modified to a polyanion acid. As the method of modifying to a polyanion acid, an ion exchange method using an ion-exchange resin, dialysis and ultrafiltration are mentioned. Among these, ultrafiltration is preferred in view of ease of operation.

A commercially available electrically conductive polymer can be also preferably used.

Examples of the commercially available conductive polymer include an electrically conductive polymer composed of poly (3,4-ethylenedioxythiophene) and polystyrene sulfonic acid (PEDOT-PSS), which is commercially available as Clevios series from H.C. Starck Co., Ltd., as PEDOT-PSS 483095 and 560598 from Aldrich Co., Ltd.), and as Denatron series from Nagase Chemtex Corporation. In addition, a polyaniline is commercially available as ORMECON series from Nissan Chemical Industries, Ltd. In the present invention, these compounds can be also preferably used.

A water-soluble organic compound may be used as a second dopant. A water-soluble organic compound usable in the present invention is not specifically limited, and can be suitably selected from known compounds. For example, an oxygen atom-containing organic compound is preferred.

The oxygen atom-containing organic compound is not specifically limited as long as it contains an oxygen atom in the molecule. Examples thereof include a hydroxyl group containing compound, a carbonyl group containing compound, an ether group containing compound and a sulfoxide group containing compound. Examples of the hydroxyl group containing compound include ethylene glycol, diethylene glycol, propylene glycol, trimethylene glycol, 1,4-butanediol and glycerin. Among these, ethylene glycol and diethylene glycol are preferred. Examples of the carbonyl group containing compound include isophorone, propylene carbonate, cyclohexanone and γ-butyrolactone. Examples of the ether group containing compound include diethylene glycol monoethyl ether. Examples of the sulfoxide group containing compound include dimethyl sulfoxide. Although these may be used singly or as an admixture of two or more kinds thereof, it is preferred that at least one compound selected from dimethyl sulfoxide, ethylene glycol and diethylene glycol be used.

### <<Hydrophilic Polymer Binder>>

The hydrophilic polymer binder in the invention which is used in the electrically conductive polymer-containing layer is not specifically limited as long as it is dissolved or dispersed in an aqueous solvent (described later). Examples thereof include a polyester resin, an acryl resin, a polyurethane resin, an acrylurethane resin, a polycarbonate resin, a cellulose resin, a polyvinyl acetal resin, and a polyvinyl alcohol resin. Examples of the polyester resin include Vilonal MD 1200, MD 1400 and MD 1480 (each produced by Toyobo Co., Ltd.).

The hydrophilic polymer binder in the invention is preferably a compound having a group capable of reacting with a cross-linking agent described later, since it can form a stronger layer. Examples of the group capable of reacting with a cross-linking agent in such a hydrophilic polymer binder, although different due to kinds of the cross-linking agent used, include a hydroxyl group, a carboxyl group, and an amino group. Among these, a hydroxyl group in the side chain of the polymer binder is most preferable.

Examples of the hydrophilic polymer binder in the invention include Polyvinyl Alcohol PVA-203, PVA-224, and PVA-420 (each produced by Kuraha Co., Ltd.); Hydroxypropylmethyl Cellulose 60SH-06, 60SH-50, 60SH-4000, and 90SH-100 (each produced by Shin-etsu Kagaku Kogyo Co., Ltd.); Methyl Cellulose SM-100 (produced by Shin-etsu Kagaku Kogyo Co., Ltd.); Cellulose Acetate L-20, L-40 and L-70 (each produced by Daicel Chemical Co., Ltd.); Carboxymethylcellulose CMC-1160 (produced by Daicel Chemical Co., Ltd.); Hydroxyethylcellulose SP-200 and SP-600 (each produced by Daicel Chemical Co., Ltd.); Acrylic acid alkyl copolymer Julimer AT-210 and AT-510 (each produced by Toa Gosei Co., Ltd.); poly(hydroxyethyl acrylate); and poly(hydroxyethyl methacrylate).

Particularly when the hydrophilic polymer binder contains the following polymer (A) in a specific amount, it can increase electrical conductivity of the electrically conductive polymer-containing layer without employing a second dopant. Further, the polymer binder has good compatibility with an electrically conductive polymer and can achieve high transparency and high smoothness. When the polyanion has a sulfo group, the sulfo group effectively works as a dehydration catalyst and as a result, the polymer (A) described below can form a dense cross-linked layer without additional addition of a cross-linking agent, which is a preferred embodiment.

The main copolymerization components of Polymer (A) are monomer units represented by the following (a1), (a2) and (a3). The Polymer (A) is a copolymer which contains 50 mol % or more of any one of the monomer units (a1) to (a3) or 50 mol % or more of the sum of the monomer units (a1) to (a3). The sum of the monomer units (a1) to (a3) in the copolymer is more preferably 80 mol % or more. Further, Polymer (A) may be a homopolymer composed of any one of the following monomer units (a1) to (a3), which is also one of the preferred embodiments.

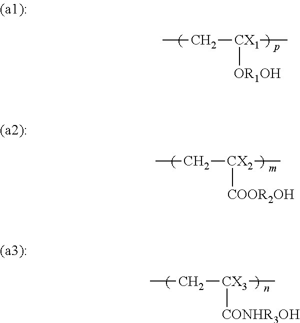

In formulae above, X₁ through X₃ independently represent a hydrogen atom or a methyl group; R₁ through R₃ independently represent an alkylene group having a carbon atom number of not more than 5; and p, m and n represent a constitution ratio (by mol %), wherein 50≦p+m+n≦100.

Polymer (A) may contain another monomer unit as the copolymerization component as long as it is soluble in an aqueous solvent. Another monomer unit is preferably a monomer component having high hydrophilicity.

In Polymer (A), the content of a component with a number average molecular weight of not more than 1,000 is preferably from 0 to 5% or less. Less content of a lower molecular weight component can improve stability of the device and can restrain barrier behavior in a direction perpendicularly to an electrically conductive layer on exchanging an electric charge perpendicularly to the electrically conductive layer.

As a method to reduce a content of a component having a number average molecular weight of not more than 1,000 to from 0 to 5% in this Polymer (A), there is mentioned a method which removes a lower molecular weight component or controls formation of a lower molecular weight component, employing a re-precipitation method, a preparative GPC, or synthesis of a monodispersed polymer by a living polymerization; or a method of can be used again. The re-precipitation method is a method which dissolves a polymer in a solvent which can dissolve the polymer, pouring the polymer solution into a less soluble solvent to precipitate the polymer, thereby removing a lower molecular weight component such as a monomer, a catalyst and an oligomer. The preparative GPC is a method which can remove the required lower molecular weight components by using, for example, a recycle preparative GPC LC-9100 (made by Japan Analytical Industry, Co., Ltd.), in which the polymer solution is passed in a polystyrene gel column, thereby dividing the polymer according to the molecular weights. In living polymerization, formation of an initiator is unchanged over reaction time, and side reactions such as a termination reaction are reduced, whereby a polymer having a uniform molecular weight can be obtained. Since the molecular weight can be adjusted by the amount added of monomers, for example, when a polymer having a molecular weight of 20,000 is prepared, formation of a lower molecular weight component can be restrained. The re-precipitation method and the living polymerization method are preferred in view of productivity.

Measurement of the number average molecular weight and the weight average molecular weight of a water soluble binder resin in the present invention can be carried out employing a generally known gel permeation chromatography (GPC). The molecular weight distribution can be represented by a ratio (a weight average molecular weight/a number average molecular weight). There is no restriction in particular to a solvent used for measurement as long as the water soluble binder is dissolved in a solvent to be used. THF, DMF and CH₂Cl₂ are preferred, THF and DMF are more preferred, and DMF is most preferred. Moreover, the measurement temperature is not specifically limited, but is preferably 40° C.

The number average molecular weight of Polymer (A) in the present invention is preferably in the range of from 3,000 to 2,000,000, more preferably in the range of from 4,000 to 500,000, and still more preferably in the range of from 5,000 to 100,000.

The molecular weight distribution of Polymer (A) in the present invention is preferably in the range of 1.01 to 1.30, and more preferably in the range of 1.01 to 1.25.

A content of components having a number average molecular weight of 1,000 or less in Polymer (A) was determined by integrating the area of a number average molecular weight of 1,000 or less in the distribution obtained by GPC, and by dividing the obtained area by the whole area of the distribution.

A solvent for living radical polymerization, which is inert under reaction conditions, is not specifically limited as long as it can dissolve a monomer and a produced polymer, and it is preferably a mixed solvent of an alcohol solvent and water. Living radical polymerization temperature, although it changes according to initiators to be used, is generally from minus 10 to 250° C., preferably from 0 to 200° C., and more preferably from 10 to 100° C.

### <<Cross-Linking>>

An electrically conductive polymer-containing layer is cross-linked by a known cross-linking agent through a residue of a polyanion which does not bond to a π conjugated electrically conductive polymer or a hydrophilic group of an aqueous binder, thereby forming a cross-linked layer.

Alternatively, when the polyanion has a sulfo group, the polyanion forms a catalyst due to heating and the OH group of the hydrophilic polymer is dehydroxylated by dehydration reaction to form an ether bondage, whereby the polymer molecules are cross-linked. This method is preferred since it can form a densely cross-linked layer without adding extra agents and is not affected adversely by unreacted or inactivated agents.

The cross-linking can be confirmed by tracing the variation of functional groups employing a state analysis method such as a conventional IR analysis, Raman analysis or XPS (X-ray photoelectron spectroscopy).

The cross-linking agent used in the invention is not specifically limited and a conventional cross-linking agent can be used. One, which is soluble in an aqueous solvent, is preferred.

The amount used of the cross-linking agent is different due to kinds of the cross-linking agent or kinds of the hydrophilic polymer resin used in combination, and is preferably from 1 to 50% by mass, and more preferably from 3 to 30% by mass, based on the amount of the hydrophilic polymer resin.

Examples of the cross-linking agent include known cross-linking agents such as epoxy-based, carbodiimide-based, melamine-based, isocyanate-based, cyclocarbonate-based, hydrazine-based and formalin-based cross-linking agents. It is preferred that a catalyst be used in combination to accelerate cross-linking reaction.

Among these cross-linking agents, an epoxy cross-linking agent, a melamine cross-linking agent and an isocyanate cross-linking agent can be especially preferably used.

An epoxy cross-linking agent is a compound which has two or more epoxy groups in the molecule. Examples thereof include Denacol™ EX313, EX614B, EX521, EX512, EX1310, EX1410, EX610U, EX212, EX622, EX721 (produced by Nagase ChemteX Corporation).

A melamine cross-linking agent used in the invention is a compound which has two or more methylol groups in the molecule. Examples of the commercially available melamine cross-linking agents include Beckamine™ M-3, FM-180, NS-19 (produced by DIC Co., Ltd.).

An isocyanate cross-linking agent used in the invention is a compound which has two or more isocyanate groups in the molecule. Examples thereof include toluene diisocyanate, xylene diisocyanate and 1,5-naphthalene diisocyanate. As commercially available isocyanates, there can be used Sumijule N3300 (produced by Sumitomo Beyer Urethane, Co. Ltd.), and Colonate L and Millionate MR-400 (each produced by Nippon Polyurethane Industry Co., Ltd.). Further, block isocyanates also are preferably used, as they can be used in an aqueous solvent.

In the invention, a cross-linking catalyst may be used. Examples thereof include, as an epoxy-based cross-linking agent, triethylene diamine or 2-methylimidazole; and include, as a melamine-based catalyst, a metal salt-based catalyst such as Catalyst M (produced by DIC Co., Ltd.), an amine-based catalyst such as Catalyst ACX or Catalyst 376 (each produced by DIC Co., Ltd.), and a composite metal salt-based catalyst such as Catalyst GT (produced by DIC Co., Ltd.). Further, a sulfuric acid or sodium sulfate can be used also as a cross-linking accelerating agent.

In the invention, a catalyst residues or inactivated agents can be removed via washing, and can reduce adverse affect on properties such as storage properties of the organic electronic device.

### [Formation of Electrically Conductive Polymer-Containing Layer]

The electrically conductive polymer-containing layer can be formed by coating and drying of a coating solution containing at least an electrically conductive polymer composed of a π conjugated electrically conductive polymer component and a polyanion component, a hydrophilic polymer binder and a solvent.

As the solvent, an aqueous solvent can be preferably used. Herein, the aqueous solvent implies a solvent containing not less than 50% by mass of water. The aqueous solvent may be pure water, which contains no another solvent. The solvent other than water in the aqueous solvent is not specifically limited as long as it is one miscible with water, and alcohol-based solvents are preferably used. Among the alcohol-based solvents, isopropyl alcohol, which has a boiling point close to that of water, is preferably used in that a layer with a smooth surface is advantageously formed.

As a coating method, there can be employed a roller coating method, a bar coating method, a dip coating method, a spin coating method, a casting method, a die coating method, a blade coating method, a gravure coating method, a curtain coating method, a spray coating method, and a doctor coating method, a letterpress (typographic) printing method, a porous (screen) printing method, a lithographic (offset) printing method, an intaglio (gravure) printing method, a spray printing method and an ink-jet printing method.

The dry thickness of the electrically conductive polymer-containing layer is preferably from 30 nm to 2,000 nm. The thickness is more preferably 100 nm or more, since when it is less than 100 nm, decrease of the conductivity becomes large, and is more preferably 200 nm or more in view of a leak preventing effect. Further, in order to maintain high transparency, it is more preferably 1,000 nm or less.

After coating, a dry process is suitably carried out in order to volatilize the solvent. The dry process conditions are not specifically limited, the dry process is preferably carried out in a temperature range where a substrate or an electrically conductive polymer-containing layer does not damage. For example, the dry process can be carried out at 80 to 150° C. for 10 seconds to 10 minutes.

In the invention, additional heat treatment is preferably carried out in order to accelerate the cross-linking reaction. The heat treatment conditions are different due to a cross-linking agent used, but additional heat treatment is preferably carried out at a temperature of from 100° C. to 200° C. for 5 minutes or more. The heat treatment temperature is more preferably from 110° C. to 160° C., and the heat treatment period of time is more preferably 15 minutes or more. The upper limit of the heat treatment period of time is not specifically limited to a processing time, but it is preferably 120 minutes or less, considering manufacturing efficiency.

### <<Washing Treatment>>

The present invention is characterized in that an electrically conductive polymer-containing layer is subjected to wet washing treatment, employing water or an aqueous solution containing an organic solvent in an amount miscible with water. The wet washing treatment washes the electrically conductive polymer-containing layer with the aqueous solution as a washing liquid, whereby conductivity inhibiting material or foreign matter present on the surface of the electrically conductive polymer-containing layer or impurities in the layer are removed, which makes it possible to prepare a transparent electrode preventing driving voltage increase, reducing current leakage and improving storage properties. An aqueous solvent is preferably used as a solvent, in order to remove lower molecular weight components of a hydrophilic binder or a polyanion, residual cross-linking agents, catalysts or impurities. The aqueous solvent implies a solvent containing not less than 50% by mass of water. Pure water, which contains no another solvent, may be used. Ultra pure water, in which foreign matter is scarcely contained, is preferably used. Herein, ultra pure water implies one having a specific resistivity of about 18 MΩ·cm at 25° C. and having a total organic carbon content (TOC) of less than 0.05 mg/L, TOC measured according to a method specified in JIS K0051. The solvent other than water in the aqueous solvent is not specifically limited as long as it is one miscible with water, and alcohol-based solvents are preferably used. Among the alcohol-based solvents, isopropyl alcohol, which has a boiling point close to that of water, is preferably used. Use of a solvent other than water is preferred since it enables removing impurities having low solubility to water. The washing liquid, as long as it does not dissolve components in filters, is preferably one filtered through various filters, since foreign matter in the washing liquid is reduced.

As a washing treatment method, there can be used a method in which a substrate with an electrically conductive polymer-containing layer is immersed in a solvent or a method in which the electrically conductive polymer-containing layer is sprayed with a solvent. A multi-stage washing treatment is preferably used. Further, an ultrasonic wave or a surfactant is preferably used in combination.

### [Multi-Stage Washing Treatment]

The multi-stage washing treatment implies washing treatment carried out employing a washing apparatus comprising two or more washing tanks provided in series. A multi-stage washing treatment is preferably used in which in two or more washing tanks provided in series a washing liquid is supplied from a washing tank on one end and overflowed. This is a method in which a washing liquid is supplied from a first washing tank on one end and overflowed to a second washing tank adjacent to the first washing tank. This enables washing in a smaller amount of the washing liquid as compared with a method in which a washing liquid is independently supplied to each of washing tanks separately provided. In the multi-stage washing treatment in the invention, three or more washing tanks are preferably provided in view of the saving of water. In view of productivity is preferred a counter-current multi-stage washing treatment in which electrodes are supplied from a washing tank on one end of the two or more washing tanks via a roll-to-roll method or a belt transport method and a fresh washing liquid is supplied from another washing tank on the other end.

In the invention, the carbon atom concentration of the surface of an electrically conductive polymer-containing layer after washing is preferably not less than 3% higher than that before washing, and more preferably from 3 to 5% higher than that before washing, whereby driving voltage increase can be advantageously prevented. This is considered to be because a hydrophilic polymer, which is present on the surface of the electrically conductive polymer-containing layer, or lower molecular weight components of the hydrophilic polymer or polyanion, which have high solvent solubility and therefore remain in the surface of the layer after drying, vary driving voltage, but these are removed via washing treatment, improving electrical conductivity. This effect is marked when the washing treatment is carried out so that the carbon atom concentration of the surface of an electrically conductive polymer-containing layer after washing is not less than 3% higher than that before washing.

The carbon atom concentration of the electrically conductive polymer-containing layer surface is one measured at a photoelectron taken-out angle of the horizon to 15° according to XPS (X-ray photoelectron spectroscopy). The measurement is carried out before and after the washing treatment, and the increment of the carbon atom concentration is determined.

### <<Structure of Organic Electronic Device>>

The organic electronic device of the invention comprises a substrate and provided thereon, a first electrode and a second electrode opposed to each other and at least one organic functional layer located between the first and second electrodes, wherein one of the first and second electrodes is a cathode electrode and the other an anode electrode. Either the first electrode or the second electrode has an electrically conductive polymer-containing layer. The electrode having an electrically conductive polymer-containing layer may be a layer composed only of the electrically conductive polymer-containing layer or a layer composed of the layer and a conventional electrically conductive electrode layer. Alternatively, a combination of an auxiliary electrode described later and the electrically conductive polymer-containing layer is preferred embodiment, in which the auxiliary electrode is included in the first electrode or the second electrode. As an electrode which does not have the electrically conductive polymer-containing layer, a conventional electrode composed of metals, oxides and the like can be used.

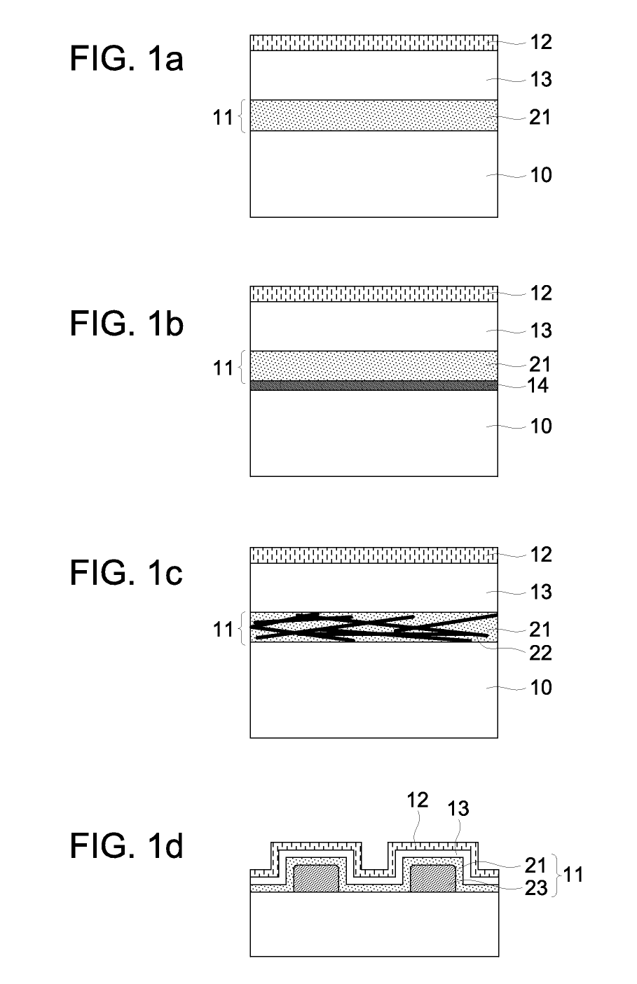

A fundamental structure of the organic electronic device of the invention is shown in FIGS. 1a through 1d.

FIG. 1a is an embodiment in which a first electrode is an electrically conductive polymer-containing layer (a single layer). FIG. 1b is an embodiment in which a first electrode is composed of two layers of an electrically conductive polymer-containing layer 14 and another electrically conductive layer. FIG. 1c is an embodiment in which an auxiliary electrode (metal wire) 22 is used in combination. FIG. 1d is an embodiment in which an auxiliary electrode (metal grid) 23 is used in combination.

As is shown in FIG. 1, the organic electronic device of the invention comprises, as a fundamental structure, a substrate 10 and provided thereon, a first electrode 11 and a second electrode 12 opposed to each other and at least one organic functional layer 13 located between the first electrode 11 and second electrode 12.

In the invention, at least one of the first electrode 11 and the second electrode 12 comprises an electrically conductive polymer-containing layer 21. As the constitution that at least one of the electrodes comprises an electrically conductive polymer-containing layer 21, there is mentioned a constitution in which at least one of the electrodes is formed from a monolayer of the electrically conductive polymer-containing layer 21 in the invention; a constitution in which the electrically conductive polymer-containing layer 21 in the invention is laminated on another known electrically conductive layer comprised of ITO, ZnO and the like; a constitution in which the electrically conductive polymer-containing layer 21 in the invention is coated on a stripe-shaped, mesh-shaped or random network-shaped electrode described later, or a constitution in which a stripe-shaped, mesh-shaped or random network-shaped electrode described later is buried in the electrically conductive polymer-containing layer 21 in the invention. The constitution is not specifically limited thereto as long as at least one of the electrodes comprises an electrically conductive polymer-containing layer 21.

Examples of the organic functional layer 13, although they are not specifically limited, include an organic emission layer, an organic photoelectron conversion layer, a liquid crystal polymer layer and the like. In the invention, an organic emission layer or an organic photoelectron conversion layer is especially preferred, in which the functional layer is thin and a current driving device.

### [Auxiliary Electrode]

In order to increase an area, it is preferred that an electrode having an electrically conductive polymer-containing layer further have an auxiliary electrode comprised of an opaque electrically conductive portion and a transparent window portion.

It is preferred that the opaque electrically conductive portion of the auxiliary electrode is composed of a metal in view of electrical conductivity. Examples thereof include gold, silver, copper, iron, nickel, and chromium. The metal of the electrically conductive portion may be an alloy, and a single layer or a multilayer.

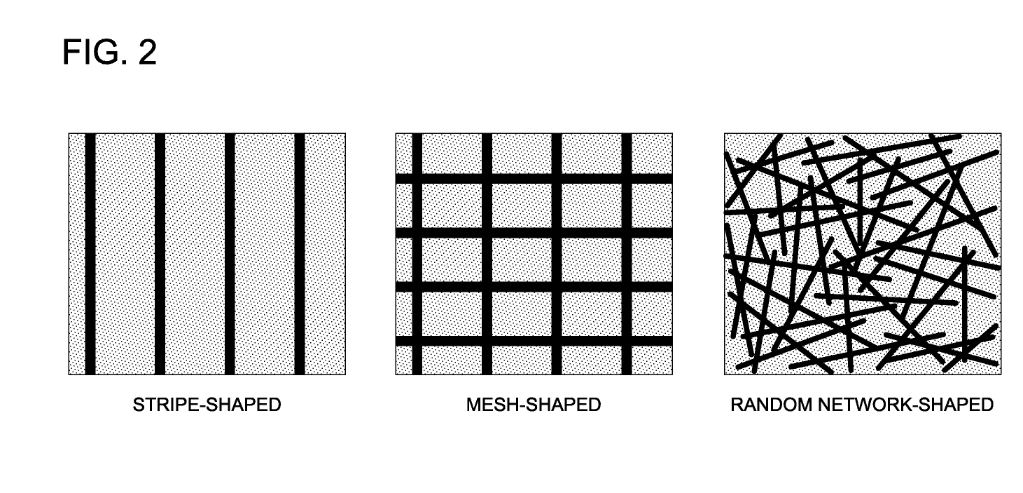

FIG. 2 is a schematic view showing one embodiment of shapes of an auxiliary electrode. The shapes of the auxiliary electrode are not specifically limited. For example, the electrically conductive portion is stripe-shaped, mesh-shaped or random network-shaped.

As a method to form an auxiliary electrode in which the electrically conductive portion is stripe-shaped, mesh-shaped or random network-shaped, a conventional method can be used without specific restriction. For example, a metal layer is formed on the whole of a metal layer and then is subjected to a conventional photolithography. Exemplarily, an electrically conductive layer is formed on a substrate employing one or two or more physical or chemical formation method such as vapor deposition, spattering, or plating. Alternatively, a metal foil is formed on a substrate through an adhesive, and is subjected to etching according to photolithography, thereby forming a desired stripe-shaped or mash-shaped auxiliary electrode.

As another method, there is a method in which a screen-printing employing an ink containing metal particles is carried out to form a predetermined shape or a method in which after gravure printing employing a catalyst ink capable of being plated or ink-jet printing is carried out to form a predetermined shape, followed by plating. As further another method, a method in which a silver halide photographic process is applied can be used. With respect to the silver halide photographic process, a method described in paragraphs [0076] to [0112] and examples of Japanese Patent O.P.I. Publication No. 2009-140750 is referred to. With respect to the method in which after gravure printing employing a catalyst ink capable of being plated is carried out, followed by plating, a method described in Japanese Patent O.P.I. Publication No. 2007-281290.

### (Random Network Structure)

With respect to the random network structure, a method disclosed in Japanese Unexamined Patent Application Publication (Translation of PCT Application) No. 2005-530005 can be used in which a metal particle-containing solution is coated and dried to spontaneously form a random network structure of electrically conductive particles.

As another method there can be a method in which a metal nanowire-containing solution is coated and dried to form a random network shape of metal nanowires, as described in Japanese Unexamined Patent Application Publication (Translation of PCT Application) No. 2009-505358.

Metal nanowires indicate fibrous substances composed of a metallic Element as a main constituent. In particular, the metal nanowires in the present invention indicate a large number of fibrous substances having a minor axis length of from an atomic scale to a nanometer (nm) size.

In order to form a long conductive path in one metal nanowire, the metal nanowires according to the present invention have an average length of preferably 3 μm or more, more preferably from 3 to 500 μm, and still more preferably from 3 to 300 μm. In addition, the relative standard deviation of the length of the metal nanowires is preferably 40% or less. Moreover, the average minor axis is not specifically limited, and is preferably smaller in view of transparency, and on the other hand, is preferably large in view of electrical conductivity. In the invention, the average minor axis of the metal nanowires is preferably from 10 to 300 nm and more preferably from 30 to 200 nm. Further, the relative standard deviation of the minor axis is preferably 20% or less.

Examples of the metals in the metal nanowires include copper, iron cobalt, gold and silver, and silver is preferred in view of electrical conductivity. The metals may be used singly, but in order to achieve both electrical conductivity and stability (sulfuration resistance and oxidation resistance of metal nanowires and migration resistance of metal nanowires), the metal nanowires may contain a metal as the main component and one ore more kinds of another metal in an arbitrary amount.

In the present invention, there is no restriction in particular to the manufacturing methods of metal nanowires. It is possible to prepare metal nanowires via various methods such as a liquid phase method or a gas phase method. Further, as the typical manufacturing methods, known manufacturing methods can be used without specific restriction. For example, the manufacturing method of Ag nanowires may be referred to Adv. Mater., 2002, 14. 833-837 and Chem. Mater., 2002, 14. 4736-4745; a manufacturing method of Au nanowires may be referred to JP-A No. 2006-233252; the manufacturing method of Cu nanowires may be referred to JP-A No. 2002-266007; while the manufacturing method of Co nanowires may be referred to JP-A No. 2004-149871. Specifically, the silver nanowire manufacturing methods described above can simply prepare Ag nanowires in an aqueous system, and silver can be preferably used since the electrical conductivity of silver is highest of all metals.

### <<Substrate>>

The transparent substrate used in the invention is not specifically limited as long as it has a high light transmission property. That is, it is preferable that the substrate is made of a transparent member to the wave length of this light that should be carried out photoelectric conversion. As the substrate, there is mentioned a glass substrate, a resin substrate or a resin film in view of its high hardness or ease of formation of an electrically conductive layer on the surface. A transparent resin film is preferably used in view of lightness and flexibility.

In the present invention, the transparent resin film, which can be preferably used as a transparent substrate, is not specifically limited, and it can be suitably selected from known ones considering material, form, structure and thickness. Typical examples of the resin film include a polyester resin film such as polyethylene terephthalate (PET), polyethylene naphthalate (PEN) or modified polyester, a polyolefin resin film such as a polyethylene (PE) resin film, a polypropylene (PP) resin film, a polystyrene resin film or a cyclic olefin resin; a vinyl resin film such as polyvinylchloride or polyvinylidene chloride; a polyether ether ketone (PEEK) resin film; a polysulfone (PSF) resin film; a polyethersulfone (PES) resin film; a polycarbonate (PC) resin film; a polyamide resin film; a polyimide resin film; an acryl resin film; and a triacetyl cellulose (TAC) resin film. A resin film can be preferably applied to the transparent resin film in the present invention, which has a transmittance for light with a visible wavelength range (380 to 800 nm) being 80% or more. Particularly, a biaxially stretched polyethylene terephthalate film, a biaxially stretched polyethylene naphthalate film, a polyethersulfone film and a polycarbonate film are preferred in view of transparency, heat resistance, ease of handling, strength and cost, and a biaxially stretched polyethylene terephthalate film and a biaxially stretched polyethylene naphthalate film are more preferred.

In order to secure wettability and adhesion property of a coating solution, the transparent substrate used in the present invention can be subjected to surface treatment or coated with an adhesion assisting layer. With respect to the surface treatment or the coating of the adhesion assisting layer, a well-known technique can be applied. As for the surface treatment, there is mentioned a surface activation process such as corona discharge treatment, flame treatment, ultraviolet treatment, high-frequency treatment, glow discharge treatment, activated plasma treatment or laser treatment.

Moreover, as for the adhesion assisting layer, there is mentioned a layer of polyester, polyamide, polyurethane, a vinyl copolymer, a butadiene copolymer, an acryl copolymer, a vinylidene copolymer or an epoxy copolymer.

### <<Organic Functional Layer Constitution>>

### [Organic EL Element]

### (Organic Emission Layer)

In the invention, the organic electronic device having an organic light emission layer comprises, in addition to an organic light emission layer, an organic layer such as a hole injecting layer, a hole transporting layer, an electron transporting layer, an electron injecting layer, a hole blocking layer or an electron blocking layer, the organic layer controlling light emission together with the light emission layer. The electrically conductive polymer-containing layer in the invention can function as a hole injection layer, and serves as a hole injection layer, but the hole injection layer may be provided separately.

Preferred embodiments of the layer constitution of the organic electronic device will be shown below, but the invention is not limited thereto.

(i) (First electrode)/Light emission layer/Electron transporting layer/(Second electrode)
(ii) (First electrode)/Hole transporting layer/Light emission layer/Electron transporting layer/(Second electrode)
(iii) (First electrode)/Hole transporting layer/Light emission layer/Hole blocking layer/Electron transporting layer/(Second electrode)
(iv) (First electrode)/Hole transporting layer/Light emission layer/Hole blocking layer/Electron transporting layer/Cathode buffering layer/(Second electrode)
(v) (First electrode)/Anode buffering layer/Hole transporting layer/Light emission layer/Hole blocking layer/Electron transporting layer/Cathode buffering layer/(Second electrode)

Herein, the light emission layer may be a monochromatic light emission layer whose emission maximum is in a wavelength region of from 430 to 480 nm, in a wavelength region of from 510 to 550 nm or in a wavelength region of from 600 to 640 nm, or may be a white light emission layer in which at least the three monochromatic light emission layers described above are laminated. An intermediate layer may be provided between two monochromatic light emission layers of the at least the three monochromatic light emission layers. The light emission layer of the organic EL Element in the invention is preferably a white light emission layer.

In the invention, examples of the light emission material or the doping material used in the organic light emission layer include anthracene, naphthalene, pyrene, tetracene, coronene, perylene, phthaloperylene, naphthaloperylene, diphenylbutadiene, tetraphenylbutadiene, coumarin, oxadiazole, bisbenzoxazoline, bisstyryl, cyclopentadiene, a quinoline metal complex, a tris(8-hydroxyquinolato)aluminum complex, a tris(4-methyl-8-hydroxyquinolato)aluminum complex, a tris(5-phenyl-8-hydroxyquinolato)aluminum complex, an aminoquinoline metal complex, a benzoquinoline metal complex, tri-(p-terphenyl-4-yl)amine, 1-aryl-2,5-di(thienyl)pvrrole derivatives, pyrane, quinacridone, rubrene, distyrylbenezene derivatives, distyrylarylene derivatives, various kinds of fluorescent dyes, rare earth metal complexes, and phosphorescence emission materials, but the invention is not specifically limited thereto. It is preferred that the light emission layer contains a light emission material in an amount of 90 to 99.5 parts by mass and a doping material in an amount of 0.5 to 10 parts by mass, the light emission material and the doping material being selected from the compounds described above. The tight emission layer is formed employing the compounds described above according to a known method including a vapor deposition method, a coating method and a transfer method. The thickness of the light emission layer is preferably from 0.5 to 500 nm, and more preferably from 0.5 to 200 nm.

### [Second Electrode]

The second electrode in the invention constitutes a cathode of an organic EL Element. The second electrode section in the invention may be a single layer containing only a conductive material, but may be a layer containing, in addition to the conductive material, a resin bearing the conductive material. For the conductive materials, there are mentioned a metal (also referred to as an electron injecting metal), an alloy, an electroconductive compound each having a low working function (not more than 4 eV) and a mixture thereof, which are used as an electrode material of the second electrode section. Concrete examples of such an electrode material include sodium, sodium-potassium alloy, magnesium, lithium, a magnesium/copper mixture, a magnesium/silver mixture, a magnesium/aluminum mixture, magnesium/indium mixture, an aluminum/aluminum oxide (Al₂O₃) mixture, indium, a lithium/aluminum mixture, and a rare-earth metal.

Among them, a mixture of an electron injecting metal and a metal higher in the working function than that of the electron injecting metal, such as the magnesium/silver mixture, magnesium/aluminum mixture, magnesium/indium mixture, aluminum/aluminum oxide (Al₂O₃) mixture, lithium/aluminum mixture, or aluminum is suitable from the viewpoint of the electron injecting capability and resistance to oxidation. The cathode can be prepared by forming a thin layer of such an electrode material by a method such as a deposition or spattering method. The sheet resistance as the cathode is preferably not more than several hundreds Ω/□, and the thickness of the layer is ordinarily from 10 nm to 5 μm, and preferably from 50 nm to 200 nm.

If metal materials are used for conductive materials of the second electrode, light, which reaches the second electrode side, is reflected and returns to the first electrode. A part of light is scattered to the back or reflected by the metal nanowires in the first electrode, however, a second electrode, employing a metal as the conductive material, enables reuse of the part of light, whereby light extraction efficiency is improved.

### [Organic Photoelectric Conversion Element]

The organic photoelectric conversion Element has a structure in which the first electrode, an organic photoelectric conversion layer (hereinafter also referred to also as a bulk heterojunction layer) having a bulk heterojunction structure (p-type semiconductor layer and n-type semiconductor layer), and the second electrode are laminated.

An intermediate layer such as an electron transporting layer may be located between the photoelectric layer and the second electrode.

### {Photoelectric Conversion Layer}

The photoelectric conversion layer is a layer converting a light energy to electric energy, and forms a bulk heterojunction layer in which a p-type semiconductor material and an n-type semiconductor material is uniformly mixed.

The p-type semiconductor material functions relatively as an electron donating material (a doner) and the n-type semiconductor material functions relatively as an electron accepting material (an acceptor).

Herein, the electron donating material and the electron accepting material is “an electron donating material and an electron accepting material which when light is absorbed, electrons migrate from the electron donating material to the electron accepting material to form a pair of electrons and holes (in the state of charge separation)”. That is, the electron donating material and the electron accepting material is not one which simply donates or accepts electrons as an electrode, but one which donates or accepts electrons through photoreaction.

As the p-type semiconductor material there are mentioned various condensed polycyclic aromatic compounds and various conjugated compounds.

Examples of the condensed polycyclic aromatic compounds include compounds such as anthracene, tetracene, pentacene, hexacene, heptacene, chrysene, picene, fulminene, pyrene, peropyrene, perylene, terylene, quoterylene, coronene, ovalene, circumanthracene, bisanthene, zethrene, heptazethrene, pyranthrene, violanthene, isoviolanthene, circobiphenyl, and anthradithiophene; and derivatives or precursors thereof.

Examples of the conjugated compounds include polythiophene and its oligomer, polypyrrole and its oligomer, polyaniline; polyphenylene and its oligomer, polyphenylene vinylene and its oligomer, polythienylene vinylene and its oligomer, polyacetylene; polydiacetylene; tetrathiafulvalene compounds; quinone compounds; cyano compounds such as tetracyanoqumodimethane; fullerene; and derivatives or mixtures thereof.

Among polythiopene and its oligomer, thiophene hexamers such as α-sexithionene, α,ω-dihexyl-α-sexithionene, α,ω-dihexyl-α-quinquethionene and α,ω-bis(3-butoxypropyl)-α-sexithionene are preferably used.

Further, examples of another p-type semiconductor polymer include polyacetylene, polyparaphenylene, polypyrrole, polyparaphenylene sulfide, polythiophene, polyphenylene vinylene, polycarbazole, polyisothianaphthene, polyheptadiyne, polyquinoline, poly aniline, substituted or non-substituted alternative copolythiophenes disclosed in Japanese Patent O.P.I. Publication Nos. 2006-36755, polymers having a condensed thiophene structure disclosed in Japanese Patent O.P.I. Publication Nos. 2007-51289 and 2005-76030 and J. Amer. Soc., 2007, p. 4112 and J. Amer. Soc., 2007, p. 7246, and thiophene copolymers disclosed in WO 2008/000664, Adv. Mater., 2007, p. 4160 and Macromolecules, 2007, Vol. 40, p 1981.

Further, examples thereof include porphyrin; organic molecular complexes such as copper phthalocyanine; tetrathiafulvalene (TTF)-tetracyanoquinodimethane (TCNQ) complex, bisethylenetetrathiafulvalene (BEDTTTF)-perchloric acid complex, BEDTTTF-iodine complex and TCNQ-iodine complex; fullerenes such as C60, C70, C76, C78 and C84; carbon nanotubes such as SWNT; dyes such as merocyanine dyes and hemicyanine dyes; σ-type conjugated copolymers such as polysilane and polygermane; and organic and inorganic mixed materials disclosed in Japanese Patent O.P.I. Publication No. 2000-16599.

Among these π-type conjugated materials, at least one selected from the group consisting of condensed polycyclic aromatic compounds such as pentacene, fullerenes, condensed tetracarboxylic acid diimides, metal phthalocyanines, and metal porphyrins is preferred.

As examples of the pentacene include pentacene derivatives having a substituent disclosed in WO 03/16599, WO 03/28125, U.S. Pat. No. 6,690,029, and JP-A No. 2004-107216; pentacene precursors disclosed in US 2003/136964; substituted acenes and their derivatives disclosed in J. Amer. Chem. Soc., vol. 127, No. 14, p. 4986, etc.

Among these compounds, preferred is a compound which has a high solubility to an organic solvent enough to carry out a solution process, and which is capable of forming a crystalline thin film after dying and of achieving high mobility. Examples of such compounds include acene compounds substituted with a trialkyl silyl ethynyl group described in J. Amer. Chem. Soc., vol. 123, p 9482 and J. Amer. Chem. Soc., vol. 130 (2008), No. 9, 2706; pentacene precursors disclosed in US 2003/136964; and precursor type compounds (precursors) such as porphyrin precursors disclosed in Japanese Patent O.P.I. Publication No. 2007-224019.

Among these, the latter precursor type compounds can be preferably used.

Precursor type compound becomes insoluble after being converted. As a result, when there are formed a positive hole transporting layer, an electron transporting layer, a positive hole block layer and an electron block layer, etc on a bulk heterojunction layer in a solution process, it will prevent dissolution of a bulk heterojunction layer. As a result, the materials which constitute the forgoing layers will not be mixed with the material which constitutes bulk heterojunction layer, and further improved efficiency and increased lifetime can be attained.

As a p-type semiconductor material, it is preferable to use a p-type semiconductor precursor which is converted to a p-type semiconductor material induced by a chemical structure change when exposed to heat, light, radiation or a vapor of a compound which triggers a chemical reaction. In particular, a compound which causes change in chemical structural with heat is preferable.

Examples of the n-type semiconductor material include fullerene, octaazaporphyrin, a perfluoro compound of a p-type semiconductor (perfluoropentacene or perfluorophthalocyanine), and a polymer compound which contains in the skeleton an aromatic carboxylic acid anhydride or imide such as naphthalene tetracarboxylic anhydride, naphthalene tetracarboxylic diimide, perylenetetracarboxylic anhydride or perylenetetracarboxylic diimide.

Among these, a fullerene-containing polymer is preferred. Examples of the fullerene-containing polymer include polymers having, in the skeleton, fullerene C60, fullerene C70, fullerene C76, fullerene C78, fullerene C84, fullerene C240, fullerene C540, mixed fullerene, fullerene nanotubes, multi layer nanotubes, mono layer nanotubes, nano-homs (cone type) or the like. As the fullerene-containing polymer, a polymer having in the skeleton fullerene C60 is preferred.

The fullerene containing polymers are broadly divided into a polymer having fullerene pendant on the side chain and a polymer having fullerene in the main chain. The polymer having fullerene in the main chain is preferred.

It is presumed that the polymer having fullerene in the main chain, when solidified, can provide packing with high density, since it has no branched structure, and as a result, can obtain high mobility.

As a method of forming a bulk heterojunction layer in which a p-type semiconductor material and an n-type semiconductor material are mixed, there is a vapor deposition method or a coating method (including a cast method and a spin coat method).

When the photoelectric device in the invention is applied to a photoelectric material such as a solar cell, the photoelectric device may be used as a single layer or as a laminated layer (tandem type).

It is preferred that the photoelectric material be sealed through a known method so as to prevent deterioration due to oxygen or moisture.

### (Transmittance)

The organic electronic device of the invention has a total light transmittance of preferably 70% or more, and more preferably 80% or more. The total light transmittance can be measured through a known method employing spectro-photometer.

### Examples

Next, the present invention will be explained in the following examples, but is not limited thereto. In the examples, “%” shows “% by mass”, unless otherwise specified.

### Example 1

### Synthetic Examples

<Living Radical Polymerization using ATRP (Atom Transfer Radical Polymerization) Method>

### (Synthesis of Initiator)

### Synthetic Example 1

### Synthesis of Methoxy Capped Oligoethylene Glycol Methacrylate 1

In a 50 ml three necked flask were placed 7.3 g (35 mmol) of 2-bromoisobutyryl bromide, 2.48 g (35 mmol) of triethylamine and 20 ml of THF. The temperature of the resulting solution was kept to be a 0° C. on an ice bath. Into the solution were dropwise added 33 ml of a 33% THF solution of oligoethylene glycol (10 g, 23 mmol, the number of ethylene glycol unit being 7 to 8, made by Laporte Specialties Co., Ltd.). After stirring the solution for 30 minutes, the temperature of the solution was raised to room temperature, and further the solution was stirred for 4 hours. THF was removed under reduced pressure employing a rotary evaporator. The residue was dissolved in ethyl ether and the resulting solution was transferred into a separation funnel. The solution in the separation funnel was added with water to wash the ether phase. After the washing was repeated 3 times, the ether phase was dried over MgSO₄. The ether was removed under reduced pressure employing a rotary evaporator to obtain 8.2 g (yield: 73%) of Initiator 1.

### (Synthesis of Water Soluble Binder Resin via Living Polymerization (ATRP))

### Synthetic Example 2

### Synthesis of poly(2-hydroxyethyl Methacrylate)

Into a Schlenk flask were placed 500 mg (1.02 mmol) of Initiator 1, 4.64 g (40 mmol) of 2-hydroxyethyl methacrylate (made by Tokyo Kasei Co., Ltd.) and 5 ml of a water-methanol mixed solvent (50:50 (v/v %)). The Schlenk flask was immersed in liquid nitrogen under reduced pressure for 10 minutes. Five minutes after the Schlenk flask was taken out from the liquid nitrogen, nitrogen gas substitution was carried out. This operation was repeated three times. Then, 400 mg (2.56 mmol) of bipyridine and 147 mg (1.02 mmol) of CuBr were added into the Schlenk flask under nitrogen atmosphere and stirred at 20° C. After 30 minutes, the reaction solution was dropped on a Kiriyama Rohto (diameter of 4 cm) provided with a filter paper and silica and recovered under reduced pressure. The solvent was removed under reduced pressure employing a rotary evaporator. The residue was dried under reduced pressure at 50° C. for 3 hours to yield 2.60 g (yield: 84%) of Water soluble binder resin 1. The produced Water soluble binder resin 1 had a number average molecular weight of 13,100 and a molecular weight distribution of 1.17, but contained no components whose number average molecular weight was less than 1,000.

The structure and molecular weight of Water soluble binder resin 1 were measured with ¹H-NMR (400 MHz, made by Nippon Denshi Co., Ltd.) and GPC (Waters 2695, made by Waters Co., Ltd.).

### <GPC Measurement Conditions>

Apparatus: Wagers 2695 (Separations Module)
Detector: Waters 2414 (Refractive Index Detector)
Column: Shodex Asahipak GF-7M HQ
Eluant: Dimethylformamide (20 mM LiBr)
Flow rate: 1.0 ml/min
Temperature: 40° C.

Similarly, poly(hydroxybutyl acrylate), poly(hydroxyethyl vinyl ether) and poly(hydroxyethyl acrylamide) (having a number average molecular weight of about 20,000 and containing no components whose number average molecular weight was less than 1,000) were prepared, and the molecular weight distributions of the poly(hydroxybutyl acrylate), poly(hydroxyethyl vinyl ether), and poly(hydroxyethyl acrylamide) were 1.19, 1.23, and 1.20, respectively.

Further, as one example of Polymer (A), Copolymer A of hydroxyethyl acrylate (60 mol %) and methyl acrylate (40 mol %) (having a number average molecular weight of about 20,000 and containing no molecules (homologue) having a molecular weight of not more than 1,000) was prepared. The molecular weight distribution of the Copolymer A was 1.23.

### <<Synthesis of Modified Water Soluble Polyester A>>

Into a reaction vessel for polycondensation were placed 35.4 parts by mass of dimethyl terephthalate, 33.63 parts by mass of dimethyl isophthalate, 17.92 parts by mass of dimethyl 5-sodiumsulfoisophthalate, 62 parts by mass of ethylene glycol, 0.065 parts by mass of calcium acetate monohydrate, and 0.022 parts by mass of manganese acetate tetrahydrate, and subjected to ester exchange reaction at 170 to 220° C. under nitrogen atmosphere while removing methanol. Subsequently, 0.04 parts by mass of trimethyl phosphate, 0.04 parts by mass of antimony trioxide as a polycondensation catalyst, and 6.8 parts by mass of 1,4-hexane dicarboxylic acid were added to the resulting reaction mixture, and esterification was carried out at a reaction temperature of from 220 to 235° C., removing substantially a theoretical amount of water. Thereafter, the inside of the reaction vessel was depressurized and heated in one hour, and polycondensation was carried out finally at 280° C. and at a pressure of not more than 133 Pa for about one hour. Thus, a modified aqueous polymer A precursor was obtained. The intrinsic viscosity of this precursor was 0.33.

The above-obtained precursor of 150 g was gradually added, with stirring, in 850 ml of pure water in a 2 liter three neck flask with a stirring impeller, a reflux condenser and a thermometer, further stirred at room temperature for 30 minutes, heated in 1.5 hours so that temperature in the inside of the flask was 98° C., and further heated at this temperature for additional three hours to obtain a solution. After that, the resulting solution was cooled in one hour to room temperature and allowed to stand overnight to obtain a solution having 15% by mass of a solid content of Modified water soluble polyester A.

### <<Synthesis of Electrically Conductive Polymer A>>

Sodium allyl carboxylate of 108 g (1 mol) were dissolved in 1000 ml of ion-exchanged water, and an ammonium persulfate oxidizing agent solution, in which 1.14 g (0.005 mol) of ammonium persulfate was dissolved in 10 ml of water, were dropwise added at 80° C. with stirring to the resulting solution and further stirred for additional 12 hours.

The resulting solution was added with 1000 ml of a 10% by mass sulfuric acid solution and about 1000 ml of the solution was removed therefrom employing an ultrafiltration method. Further, the resulting solution was added with 2000 ml of an ion-exchanged water and about 2000 ml of the solution was removed therefrom employing an ultrafiltration method. The above ultrafiltration process was repeated three times. Water was removed from the resulting solution under reduced pressure. Thus, a colorless solid component was obtained.

Successively, 11.4 g (0.1 mol) of 3-methoxythiophene was mixed with a solution in which 16.2 g (0.15 mol) of polyallyl carboxylic acid were dissolved in 2000 ml of an ion-exchanged water.

To the resulting solution was slowly added while stirring at 20° C. with an oxidizing catalyst solution in which 29.64 g of ammonium persulfate and 8.0 g (0.02 mol) of ferric sulfate were dissolved in 200 ml of ion-exchanged water, and then reacted with stirring for 12 hours.

The resulting reaction solution was added with 2000 ml of ion-exchanged water, and about 2000 ml of the solution was removed therefrom employing an ultrafiltration method. This process was repeated three times.

Further, the resulting solution was added with 2000 ml of ion-exchanged water, and about 2000 ml of the solution was removed therefrom employing an ultrafiltration method. This process was repeated five times. Thus, a 15% by mass solution of a blue polyallyl carboxylic acid doped poly(3-methoxythiophene) was obtained.

### (Preparation of Organic EL Element Sample 101: Reference Example)

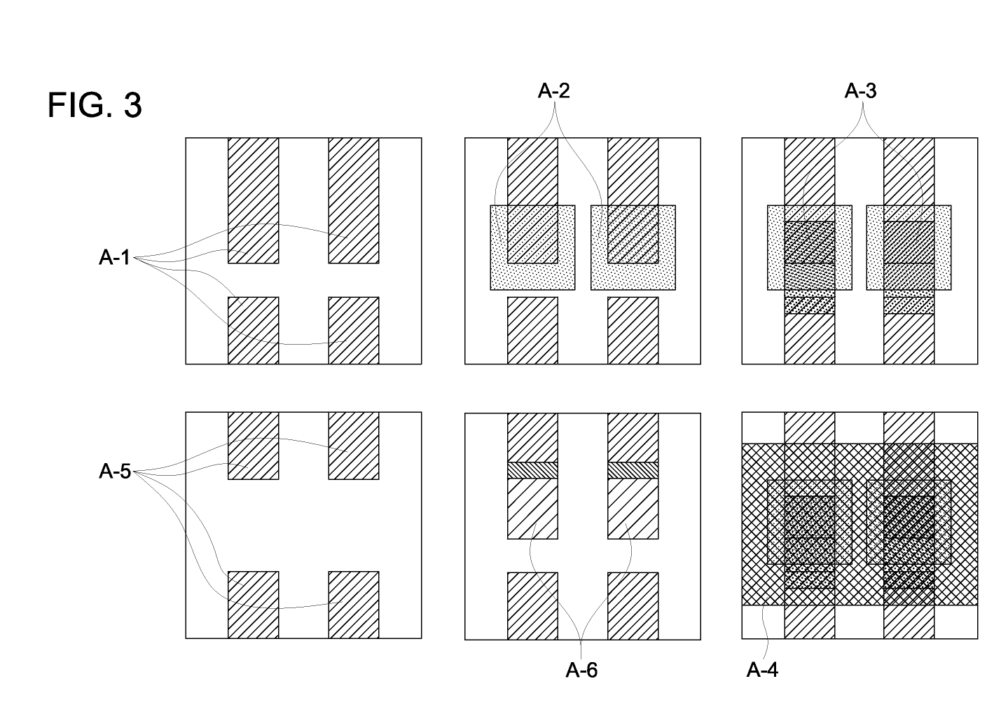

A 150 nm ITO (indium tin oxide) layer was formed on a 30 mm×30 mm×1.1 mm glass substrate and subjected to patterning according to photolithography as shown in (A-1) of FIG. 3. The resulting material was immersed in isopropyl alcohol and subjected to ultrasonic washing for 10 minutes, employing an ultrasonic washing machine BLANSONIC 3510 J-MT (produced by Emerson Japan, Ltd.).

As an electrically conductive polymer-containing layer, PEDOT-PSS CELEVIOS PAI 4083 (solid component: containing 1.5%) (produced by H.C. Starck Co., Ltd.) was coated with a spin coater, adjusting the rotation number so as to give a dry thickness of 30 nm. Subsequently, the region except for A-2 in FIG. 3 being washed off employing a pure water impregnated cotton bar, the resulting material was heat treated at 150° C. for 30 minutes, employing a hot plate. Thus, a first electrode was formed.

A hole transporting layer and another layer formed after the hole transporting layer was formed according to vapor deposition. Each of the vapor deposition crucibles in a commercially available vacuum vapor deposition apparatus was charged with an optimum amount of each constitutional material necessary to form each constitutional layer. As the vapor deposition crucibles were used ones made of a resistance heat material made of molybdenum or tungsten.

### <Formation of Hole Transporting Layer>

Pressure being reduced to a vacuum degree of 1×10⁻⁴ Pa, the vapor deposition crucible charged with Compound 1 was heated by current application and Compound 1 was deposited on the region (A-2) of FIG. 3 on the first electrode at a deposition rate of 0.1 nm/sec, whereby a 30 nm thick hole transporting layer was formed.

### <Formation of Light Emission Layer>

Subsequently, a light emission layer was formed according to the following procedures.

Compound 2, Compound 3 and Compound 5 were co-deposited on the region (A-2) of FIG. 3 on the hole transporting layer at a deposition rate of 0.1 nm/sec so as to give a concentration of Compound 1 of 13% by mass and a concentration of Compound 3 of 3.7% by mass. Thus, a 10 nm thick green red color phosphorescence right emission layer was formed which had a wavelength providing emission maximum of 622 nm.

Subsequently, Compound 4 and Compound 5 were co-deposited on the region (A-2) of FIG. 3 on the light emission layer formed above at a deposition rate of 0.1 nm/sec so as to give a concentration of Compound 4 being 10% by mass. Thus, a 15 nm thick blue color phosphorescence light emission layer was formed which had a wavelength providing emission maximum of 471 nm.

### <Formation of Hole Blocking Layer>

Further, Compound 6 was vapor deposited on the region (A-2) of FIG. 3 on the light emission layer to form a 5 nm thick hole blocking layer.

### <Formation of Electron Transporting Layer>

Successively, CsF and Compound 6 were co-deposited on the region (A-2) on the hole blocking layer to give 10% of CsF by thickness ratio to form a 45 nm thick electron transporting layer.

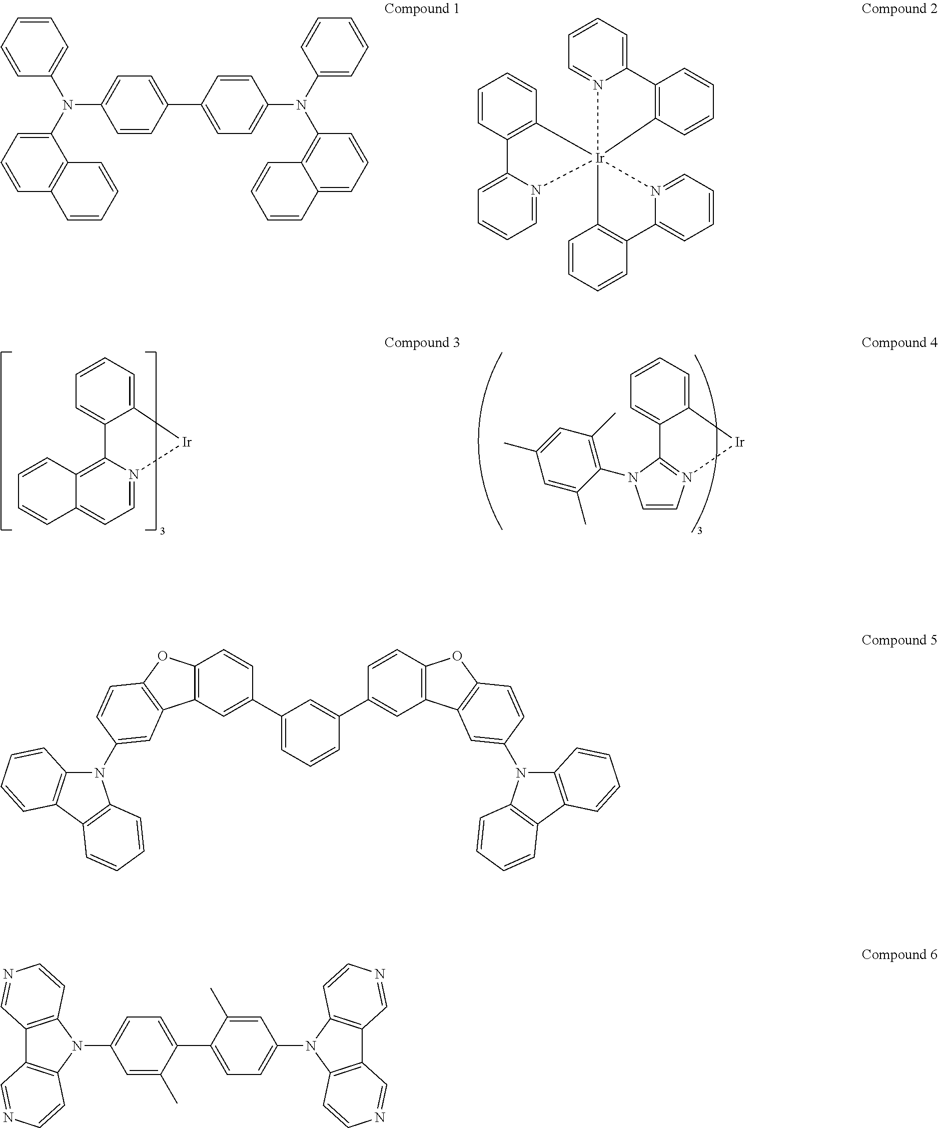

### Second Electrode

### <Formation of Cathode Electrode>

Al was vapor deposited on the region (A-3) of FIG. 3 on the resulting electron transporting layer under a vacuum pressure of 5×10⁻⁴ Pa to form a cathode electrode having a thickness of 100 nm.

### <Formation of Sealing Film>

A 300 nm thick Al₂O₃ was vapor deposited on a polyethylene terephthalate substrate to prepare a flexible sealing member. An adhesive agent being coated, the flexible sealing member was laminated on the region (A-4) of FIG. 3, heated to cure the adhesive agent and sealed. The ITO located outside the sealing member was used as externally taken-out terminals of the anode and cathode electrodes. Thus, Organic EL Element Sample 101 was prepared.

### (Preparation of Organic EL Element Sample 102: Comparative Sample)

Organic EL Element Sample 102 was prepared in the same manner as Organic EL Element Sample 101, except that PEDOT-PSS was replaced with PEDOT-PSS CLEVIOS PH510 (solid component 1.89%) (produced by H.C. Starck Co., Ltd.) and the thickness of the electrically conductive polymer-containing layer was changed to 300 nm.

### (Preparation of Organic EL Element Sample 103: Inventive Sample)

Organic EL Element Sample 103 was prepared in the same manner as Organic EL Element Sample 101, except that the patterns of ITO were formed as shown in (A-5) of FIG. 3 (which were used as taken-out electrodes), a coating solution 103 described below was coated to form a 300 nm thick electrically conductive polymer-containing layer whose pattern was shown in (A-6) of FIG. 3, and washing treatment A described later was carried out after formation of the first electrode.

### (Coating Solution 103)

| | |
|---|---|
| PEDOT-PSS CLEVIOS PH510 (Solid component 1.89%) | 1.59 g |
| (produced by H.C. Starck Co., Ltd.) | |
| Poly(hydroxyethyl acrylate) (Synthetic example 2, solid | 0.35 g |
| component 20% aqueous solution) | |
| Dimethylsulfoxide (DMSO) | 0.08 g |

### (Washing Treatment A)

A mixture of water/isopropyl alcohol (=8:2 by mass) was placed in a beaker as a washing solvent and stirred. Then, the glass substrate with the first electrode formed was immersed in the mixture for three minutes.

The resulting substrate was washed with flowing water for 5 minutes, and placed and dried at 120° C. for 30 minutes on a hot plate.

### (Preparation of Organic EL Element Sample 104: Inventive Sample)

Organic EL Element Sample 104 was prepared in the same manner as Organic EL Element Sample 101, except that a coating solution 104 described below was coated to form a 300 nm thick electrically conductive polymer-containing layer, and washing treatment A described above was carried out after formation of the first electrode.

### (Coating Solution 104)

| | |
|---|---|
| PEDOT-PSS CLEVIOS PH510 (Solid component 1.89%) | 1.59 g |
| (produced by H.C. Starck Co., Ltd.) | |
| Poly(hydroxyethyl acrylate) (Synthetic example 2, solid | 0.35 g |
| component 20% aqueous solution) | |

### (Preparation of Organic EL Element Sample 105: Comparative Sample)

Organic EL Element Sample 105 was prepared in the same manner as Organic EL Element Sample 104, except that washing treatment A was not carried out.

### (Preparation of Organic EL Element Sample 106: Inventive Sample)

Organic EL Element Sample 106 was prepared in the same manner as Organic EL Element Sample 104, except that the content ratio of an electrically conductive polymer (CP) to a hydrophilic polymer binder (B) (CP/B) was one as shown in Table 1 and the content of poly(hydroxyethyl acrylate) (Synthetic example 2, solid component 20% aqueous solution) was changed to 0.15 g.

### (Preparation of Organic EL Element Sample 107: Inventive Sample)

Organic EL Element Sample 107 was prepared in the same manner as Organic EL Element Sample 104, except that the polymer was changed to poly(hydroxybutyl acrylate).

### (Preparation of Organic EL Element Sample 108: Inventive Sample)

Organic EL Element Sample 108 was prepared in the same manner as Organic EL Element Sample 104, except that the polymer was changed to poly(hydroxyethyl vinyl ether).

### (Preparation of Organic EL Element Sample 109: Inventive Sample)

Organic EL Element Sample 109 was prepared in the same manner as Organic EL Element Sample 104, except that the polymer was changed to poly(hydroxyethyl acrylamide).

### (Preparation of Organic EL Element Sample 110: Inventive Sample)

Organic EL Element Sample 110 was prepared in the same manner as Organic EL Element Sample 104, except that the electrically conductive polymer was changed to 2.00 g of PEDOT-PSS CELEVIOS PAI 4083 (solid component: containing 1.5%) (produced by H.C. Starck Co., Ltd.).

### (Preparation of Organic EL Element Sample 111: Comparative Sample)

Organic EL Element Sample 111 was prepared in the same manner as Organic EL Element Sample 110, except that the washing treatment A was not carried out.

### (Preparation of Organic EL Element Sample 112: Inventive Sample)

Organic EL Element Sample 112 was prepared in the same manner as Organic EL Element Sample 104, except that the electrically conductive polymer was changed to PEDOT-PSS 4083095 (produced by H.C. ALDRICH Co., Ltd.).

### (Preparation of Organic EL Element Sample 113: Comparative Sample)

Organic EL Element Sample 113 was prepared in the same manner as Organic EL Element Sample 112, except that the washing treatment A was not carried out.

### (Preparation of Organic EL Element Sample 114: Comparative Sample)

Organic EL Element Sample 114 was prepared in the same manner as Organic EL Element Sample 104, except that a coating solution 114 described below was coated to form an electrically conductive polymer-containing layer.

### (Coating Solution 114)

| | |
|---|---|
| PEDOT-PSS CLEVIOS PH510 (Solid component 1.89%) | 1.59 g |
| (produced by H.C. Starck Co., Ltd.) | |
| Polyvinyl alcohol PVA-235 (aqueous 2% solid component | 0.35 g |
| solution) (produced by KUREHA Corporation) | |
| Dimethyl sulfoxide (DMSO) | 0.08 g |
| DENACOL EX521 (produced by Nagase Chemtex Corporation) | 0.07 g |
| An aqueous 10% by mass ammonium sulfate solution | 0.07 g |

### (Preparation of Organic EL Element Sample 115: Comparative Sample)

Organic EL Element Sample 115 was prepared in the same manner as Organic EL Element Sample 114, except that the washing treatment A was not carried out.

### (Preparation of Organic EL Element Sample 116: Inventive Sample)

Organic EL Element Sample 116 was prepared in the same manner as Organic EL Element Sample 104, except that a coating solution 116 described below was coated to form an electrically conductive polymer-containing layer.

### (Coating Solution 116)

| | |
|---|---|
| PEDOT-PSS CLEVIOS PH510 (Solid component 1.89%) | 1.59 g |
| (produced by H.C. Starck Co., Ltd.) | |
| Modified aqueous polyester A (with a solid component of 15%) | 0.20 g |
| Dimethyl sulfoxide (DMSO) | 0.08 g |
| An aqueous solution with a solid component of 10% in which | 0.07 g |
| Beckamine M-3 (produced by DIC Co., Ltd.) was diluted | |
| with water | |
| An aqueous solution with a solid component of 1% in which | 0.07 g |
| Catalyst ACX (produced by DIC Co., Ltd.) was diluted with | |
| water | |

### (Preparation of Organic EL Element Sample 117: Comparative Sample)

Organic EL Element Sample 117 was prepared in the same manner as Organic EL Element Sample 116, except that the washing treatment A was not carried out.

### (Preparation of Organic EL Element Sample 118: Inventive Sample)

Organic EL Element Sample 118 was prepared in the same manner as Organic EL Element Sample 104, except that the washing treatment was changed to washing treatment B described below.

### (Washing Treatment B)

The glass substrate with the first electrode was immersed in Semicoclean (Furuich Chemical Corporation) and subjected to ultrasonic washing for 10 minutes employing an ultrasonic washing machine BRANSONIC 3510J-MT (produced by Emerson Japan, Ltd.).

The resulting substrate was washed with flowing water for 5 minutes, and placed and dried on a hot plate at 120° C. for 30 minutes.

### (Preparation of Organic EL Element Sample 119: Comparative Sample)

Organic EL Element Sample 119 was prepared in the same manner as Organic EL Element Sample 104, except that a 300 nm thick electrically conductive polymer-containing layer was formed employing a monomer-containing coating solution 119 as described below, and cured by exposure of a high pressure mercury lamp.

### (Preparation of Coating Solution 119)

Hydroxymethyl acrylate of 4.28 g was added to 100 g of PEDOT-PSS CLEVIOS PH510 (solid content of 1.89%) (produced by H.C, Starck Co., Ltd.), and uniformly dispersed. After that, the resulting dispersion was subjected to evaporation to remove the moisture, and added with 0.13 g of trimethylolpropane triacrylate and IRGACURE 754 (produced by Ciba Japan Co., Ltd.) as a polymerization initiator. Thus, a coating solution 119 was prepared.

### (Preparation of Organic EL Element Sample 120: Inventive Sample)

Organic EL Element Sample 120 was prepared in the same manner as Organic EL Element Sample 104, except that the patterns of ITO as an externally taken-out terminal were formed as shown in (A-5) of FIG. 3, the patterns of an auxiliary electrode composed of silver nanowires were formed as shown in (A-6) of FIG. 3 according to a method as described below, and then the electrically conductive polymer-containing layer was formed on them.

Referring to the method described in Adv. Mater., 2002, 14, p. 833-837, filtered employing a ultrafiltration membrane, silver nanowires with an average minor axis length of 75 nm and an average length of 35 μm were prepared using PVP K30 (with a molecular weight of 50,000) (produced by ISP Co., Ltd.), and washed with water to obtain the silver nanowires. The resulting silver nanowires were re-dispersed in an aqueous solution containing hydroxymethylcellulose 60SH-50 (produced by Shin-etsu Kagaku Kogyo Co., Ltd.) in an amount of 25% by mass based on the silver amount. Thus, a silver nanowire dispersion solution was prepared.

The silver nanowire dispersion solution was coated on the substrate through a spin coater and dried to give a silver nanowire coating amount of 0.06 g/m², thereby forming a silver nanowire coating film.

The following Metal particle removing solution BF-1, whose viscosity was adjusted to 10 Pa·s (1000 cP) with sodium carboxymethylcellulose (C5013 produced by SIGMA-ALDRICH Co., Ltd., hereinafter also referred to as CMC), was screen-printed on the silver nanowire coating film in a pattern reverse to that of (A-6) of FIG. 3 to give a coating layer of 30 μm. The resulting coating layer, after allowed to stand one minute, was immersed in water for 30 seconds to remove the printed Metal particle removing solution BF-1. Thus, auxiliary electrode composed of silver nanowires was prepared.

### <Preparation of Metal Particle Removing Solution BF-1>

| | |
|---|---|
| Ferric ammonium ethylenediaminetetraacetate | 60 g |
| Ethylenediaminetetraacetatic acid | 2.0 g |
| Sodium metabisulfite | 15 g |
| Ammonium thiosulfate | 70 g |
| Maleic acid | 5.0 g |

Pure water was added to the above composition to make a 1 liter solution and adjusted to a pH of 5.5 with sulfuric acid or aqueous ammonia. Thus, Metal particle removing solution BF-1 was prepared.

### (Preparation of Organic EL Element Sample 121: Comparative Sample)

Organic EL Element Sample 121 was prepared in the same manner as Organic EL Element Sample 120, except that the washing treatment was not carried out

Organic EL Element Sample 122 (inventive Sample) and Organic EL Element Sample 123 (Comparative Sample) were prepared in the same manner as Organic EL Element Sample 120 and 121, respectively, except that a silver particle self-organized film was formed as an auxiliary electrode (with a random network structure) employing the following emulsion.

Four grams of silver powder (with a maximum particle diameter less than 0.12 μ) in place for silver nanowires, 30 g of 1,2-dichloroethane, and 0.2 g of a urea-modified cellulose binder of ethylcellulose with a molecular weight from 100,000 to 200,000 were mixed and homogenized for 1.5 minutes with an ultrasonic wave with an output power of 180 W, and then added with 15 ml of distilled water. The resulting emulsion was further homogenized for 30 seconds with an ultrasonic wave with an output power of 180 W.

### (Preparation of Organic EL Element Sample 124: Inventive Sample)

Organic EL Element Sample 124 was prepared in the same manner as Organic EL Element Sample 104, except that the electrically conductive polymer-containing layer was formed employing the following coating solution 124.

### (Coating Solution 124)

| | |
|---|---|
| Electrically conductive polymer (solid content: 1.5%) | 2.00 g |
| Poly(hydroxyethyl acrylate) | 0.35 g |
| (Synthetic example 2, aqueous solution having a solid | |
| content of 20%) | |
| DENACOL EX521 (produced by Nagase Chemtex Corporation) | 0.07 g |
| Aqueous 1% by mass ammonium sulfate solution | 0.07 g |

### (Preparation of Organic EL Element Sample 125: Comparative Sample)

Organic EL Element Sample 125 was prepared in the same manner as Organic EL Element Sample 124, except that the washing treatment A was not carried out.

### (Preparation of Organic EL Element Sample 126: Inventive Sample)

Organic EL Element Sample 126 was prepared in the same manner as Organic EL Element Sample 104, except that the content ratio of the electrically conductive polymer and the polymer was adjusted to those as shown in Table 1.

The details of the electrically conductive polymer, auxiliary electrode, hydrophilic polymer binder and washing treatment, which are abbreviated as shown in Table 1, are as follows.
510: PEDOT-PSS CLEVIOS PH510 (produced by H.C. Starck Co., Ltd.)
4083: PEDOT-PSS CLEVIOS P AI 4083 (produced by H.C. Starck Co., Ltd.)
483095: PEDOT-PSS 483095 (produced by ALDRICH Co., Ltd.)
Silver NW: Silver nanowires
Self-organization silver: Self-organized silver particle film
P1: Poly(hydroxyethyl acrylate)
P2: Poly(hydroxybutyl acrylate)
P3: Poly(hydroxyethyl vinyl ether)
P4: Poly(hydroxyethyl acrylamide)
P5: PVA-235 (produced by KUREHA Corporation)
P6: Modified water soluble polyester A
P7: Hydroxyethyl acrylate-methyl acrylate copolymer
M1: Hydroxyethyl acrylate (monomer)

The “None” in the columns of Auxiliary electrode and Washing treatment means that an auxiliary electrode was not used and that wet washing treatment was not carried out, respectively. In the washing treatment column, the symbol A means that wet washing treatment was carried out using the washing liquid A, and the symbol B means that wet washing treatment was carried out using the washing liquid B.

### (Evaluation of Organic EL Element Sample)

A direct current voltage was applied to each of Organic EL Element Samples (Samples 102 through 126), employing Source-Measure Unit 2400 Type produced by KEITHLEY Co., Ltd. to produce light emission at 1000 cd/m².

Five specimens of each sample were prepared. As one specimen had two emission portions, ten emission portions in each sample were evaluated.

With respect to stability of driving voltage, storage stability and Element lifetime, the most preferred result is shown, and Organic EL Element Sample 110 being used as a reference, each sample was evaluated as follows:

### (Short-Circuiting Between Electrodes)

A rectification ratio was employed as measure for showing the short-circuiting. Positive (plus) voltage was applied and reversed negative (minus) voltage being applied to electrodes, (absolute value of current during emission)/(absolute value of current at the reverse) the rectification ratio was determined and this value was defined as a rectification ratio. The protrusions or foreign matter increases this ratio. When this ratio is 1, it shows the state of complete leakage. The ratio is preferably not less than 100, and more preferably not less than 1000. Evaluation was carried out according to the following criteria: In order to meet requirement for large-area, ranking 3 or more in the evaluation is necessary, ranking 4 or more is preferred.

The rectification ratio of Organic EL Element Sample 101 prepared as a reference sample was 1, resulting in marked short-circuiting between electrodes.
5: Eight or more emission portions had a rectification ratio of not less than 1000, and there were no emission portions having a rectification ratio of less than 100.
4: Five or more emission portions had a rectification ratio of not less than 1000, and there were no emission portions having a rectification ratio of less than 100.
3: There were no samples which did not emit light, but one of the ten emission portions had a rectification ratio less than 100.
2: There were one to four samples, which did not emit or which had a rectification ratio less than 100.
1: There were five or more samples, which did not emit or which had a rectification ratio less than 100.

### (Driving Voltage Stability)

The average of the samples which emitted light was set as driving voltage of each sample, and a driving voltage ratio of each sample to the driving voltage of Sample 110 was determined. Driving voltage stability was evaluated according to the following criteria.

Ranking 4 or higher is preferred and ranking 5 is most preferred.
5: The ratio was less than 105%.
4: The ratio was from 105% to less than 110%.
3: The ratio was from 110% to less than 120%.
2: The ratio was from 120% to less than 130%.
1: The ratio was not less than 130%.

### (Storage Stability)

Each sample was stored at 75° C. in a thermostatic apparatus, and taken out from the apparatus every 12 hours. Voltage applied when the sample was caused to emit at an initial luminance of 1000 cd/m² was applied to the sample taken out, luminance was measured, and time taken until the luminance reduced by half was determined. A ratio of each sample to the driving voltage of Sample 110 was determined. Evaluation was made according to the following criteria.

Ranking 4 or higher is preferred and ranking 5 is most preferred.
5: The ratio was not less than 90%.
4: The ratio was from 70% to less than 90%.
3: The ratio was from 50% to less than 70%.
2: The ratio was from 10% to less than 50%.
1: The ratio was less than 10%.

### (Lifetime)

Each sample was caused to continuously emit at an initial luminance of 5000 cd/m² and time taken until the luminance reduced by half was determined.

a ratio of the lifetime of each sample to that of Organic EL Element Sample 110 was determined. Evaluation was made according to the following criteria.

Ranking 3 or higher is preferred and ranking 4 or higher is more preferred.
5: The ratio was not less than 90%.
4: The ratio was from 70% to less than 90%.
3: The ratio was from 50% to less than 70%.
2: The ratio was from 10% to less than 50%.
1: The ratio was less than 10%.

### (Transmittance)

With respect to transmittance, the transmittance of the electrically conductive layer pattern portions e was determined in the wavelength range from 400 to 700 nm through AUTOMATIC HAZE METER (MODEL TC-HIIIDP) produced by Tokyo Denshoku Co., Ltd.

All of the inventive samples had a transmittance of not less than 75%, showing good results.

(Surface Carbon Atom Concentration before and after Washing Treatment)

The atom concentration is measured at a photoelectron taken-out angle of the horizon to 15° according to XPS (X-ray photoelectron spectroscopy). The measurement is carried out before and after the washing treatment, and the increment of the carbon atom concentration is determined.

The atomic concentration by number is defined by the following formula.

Atomic concentration by number % (atomic concentration)=(the number of carbon atoms/the total number of all atoms)×100

In the present invention, there was used a surface analyzer, ESCALAB-200R, produced by VG Scientific Co. Specifically, measurement was conducted using Magnesium for an X-ray anode at an output of 600 W (accelerating voltage: 15 kV, emission current: 40 mA). Energy resolving power was set at 1.5 eV to 1.7 eV when defined in a half width of a clean Ag3d5/2 peak.

First, measurement was performed at data incorporating intervals of 0.2 eV in a bonding energy range of 0 eV to 1100 eV to determine the elements to be detected.

Then, with respect to all the detected elements except for etching species, narrow scanning for a photoelectron peak giving a maximum intensity was performed at data incorporating intervals of 0.2 eV to determine spectra of the respective elements.

To inhibit occurrence of difference in determined content result, caused by the differences of measurement instruments or computers, the obtained spectrum was transferred to COMMON DATA PROCESSING SYSTEM, produced by VAMAS-SCA-JAPAN Co. (preferably after Ver. 2.3) and processed by the same software to determine the contents of the respective targeted elements (carbon, nitrogen, oxygen, fluorine, sulfur and the like) in terms of atomic concentration by number (atomic concentration: at %).

Prior to quantitative analysis, calibration of the Count Scale was conducted to perform a smoothing treatment of 5 points. In the quantitative analysis was used a peak area intensity (cps*eV). This background treatment employed the Shirley method. The Shirley method is referred to D. A. Shirley, Phys. Rev., B5, 4709 (1972).

### (Cross-Linking)

The electrically conductive polymer-containing layer used in the device of the invention was subjected to IR analysis, and it has proved that absorption derived from the cross-linking is formed.

TABLE 1

| | | | | | Thickness | | | | | | | |
|---|---|---|---|---|---|---|---|---|---|---|---|---|
| | | | | | of Electrically | | | | | | | |
| | | | | | Conductive | | | Short- | | | | |
| | Electrically | | Hydrophilic | | Polymer- | | | Circuiting | Driving | | | |
| | Conductive | Auxiliary | Polymer | | containing | Washing | ΔC | Between | Voltage | Storage | | |
| Samples | Polymer | Electrode | Binder | CP/B | Layer | Treatment | at % | Electrodes | Stability | Stability | Lifetime | Remarks |
| 102 | 510 | None | — | — | 300 nm | None | 0 | 2 | 3 | 3 | 2 | Comp. |
| 103 | 510 + DMSO | None | P1 | 3/7 | 300 nm | A | 4.1 | 5 | 5 | 5 | 4 | Inv. |
| 104 | 510 | None | P1 | 3/7 | 300 nm | A | 3.9 | 5 | 5 | 5 | 4 | Inv. |
| 105 | 510 | None | P1 | 3/7 | 300 nm | None | 0 | 4 | 3 | 3 | 2 | Comp. |
| 106 | 510 | None | P1 | 5/5 | 300 nm | A | 3.5 | 5 | 5 | 5 | 4 | Inv. |
| 107 | 510 | None | P2 | 3/7 | 300 nm | A | 2.6 | 5 | 4 | 5 | 3 | Inv. |
| 108 | 510 | None | P3 | 3/7 | 300 nm | A | 3.7 | 4 | 5 | 5 | 5 | Inv. |
| 109 | 510 | None | P4 | 3/7 | 300 nm | A | 4.1 | 5 | 5 | 4 | 5 | Inv. |
| 110 | 4083 | None | P1 | 3/7 | 300 nm | A | 4 | 5 | 5 | 5 | 5 | Inv. |
| 111 | 4083 | None | P1 | 3/7 | 300 nm | None | 0 | 4 | 3 | 3 | 2 | Comp. |
| 112 | 483095 | None | P1 | 3/7 | 300 nm | A | 4 | 5 | 5 | 5 | 4 | Inv. |
| 113 | 483095 | None | P1 | 3/7 | 300 nm | None | 0 | 4 | 3 | 3 | 2 | Comp. |
| 114 | 510 + DMSO | None | P5 | 5/5 | 300 nm | A | 2.3 | 4 | 4 | 5 | 3 | Inv. |
| 115 | 510 + DMSO | None | P5 | 5/5 | 300 nm | None | 0 | 3 | 2 | 3 | 2 | Comp. |
| 116 | 510 + DMSO | None | P6 | 5/5 | 300 nm | A | 2.3 | 4 | 4 | 4 | 3 | Inv. |
| 117 | 510 + DMSO | None | P6 | 5/5 | 300 nm | None | 0 | 3 | 2 | 3 | 2 | Comp. |
| 118 | 510 | None | P1 | 3/7 | 300 nm | B | 4.3 | 5 | 5 | 5 | 4 | Inv. |
| 119 | 510 | None | M1 | 3/7 | 300 nm | A | 1.2 | 2 | 2 | 2 | 2 | Comp. |
| | | | (Monomer) | | | | | | | | | |
| 120 | 510 | Silver NW | P1 | 3/7 | 300 nm | A | 3.8 | 5 | 5 | 5 | 4 | Inv. |
| 121 | 510 | Silver NW | P1 | 3/7 | 300 nm | None | 0 | 4 | 3 | 3 | 2 | Comp. |
| 122 | 510 | SO Ag | P1 | 3/7 | 500 nm | A | 3.8 | 5 | 5 | 5 | 4 | Inv. |
| 123 | 510 | SO Ag | P1 | 3/7 | 500 nm | None | 0 | 4 | 3 | 3 | 2 | Comp. |
| 124 | CP-A | None | P1 | 3/7 | 300 nm | A | 3.8 | 4 | 4 | 3 | 3 | Inv. |
| 125 | CP-A | None | P1 | 3/7 | 300 nm | None | 0 | 3 | 2 | 3 | 2 | Comp. |
| 126 | 510 | None | P7 | 3/7 | 300 nm | A | 3.9 | 5 | 5 | 5 | 4 | Inv. |

Inv.: Inventive,
Comp.: Comparative
“CP/B” represents a content ratio of Electrically Conductive Polymer (CP) to Hydrophilic polymer binder (B).
“ΔC at %” represents increment of surface carbon concentration after washing treatment.
“SO Ag” represents Self-Organized Silver.
“CP-A” represents Electrically Conductive Polymer A.

As is apparent from Table 1, the inventive Organic EL Element Samples excel in prevention of short-circuiting between electrodes, driving voltage stability, storage stability and lifetime. That is, it has proved that the present invention can prevent short-circuiting between electrodes and improve lifetime without deteriorating transmittance, driving voltage stability and storage stability of an organic electronic device (an organic EL element). This effect is pronounced when the hydrophilic polymer binder in the invention comprises the polymer (A).

### Example 2

(Preparation of Organic EL Element Samples 201 through 208: Inventive Samples)

Organic EL Element Samples 201, 202, 203 and 204 were prepared in the same manner as Organic EL Element Samples 103, 104, 110 and 120 in Example 1, respectively, except that after the first electrode was formed, washing treatment 1 described later was carried out instead of the washing treatment using the washing liquid A.

Similarly, Organic EL Element Samples 205, 206, 207 and 208 were prepared in the same manner as Organic EL Element Samples 103, 104, 110 and 120 in Example 1, respectively, except that after the first electrode was formed, washing treatment 2 described later was carried out instead of the washing treatment using the washing liquid A.

### (Preparation of Organic EL Element Sample 209: Comparative Sample)

Organic EL Element Sample 209 as a comparative sample was prepared in the same manner as Organic EL Element Sample 103 in Example 1, except that the washing treatment was not carried out.

### (Washing Treatment 1)

The electrode was washed in a multi-stage washing apparatus with three washing tanks. Transporting distance in each tank was 3 m, 3 m, and 4 m. As a washing liquid, ultra pure water, which was prepared employing a Milli-Q water production apparatus Milli-Q Advantage (produced by Nippon Millipore Co., Ltd.), was used. The electrode was transported according to a belt transporting method, fixed to the belt, introduced in the washing tank, and discharged from the washing tank at a rate of 1 m/min. The flow rate of the washing liquid in the multi-stage washing was 50 ml/min. In the multi-stage washing apparatus above, a washing liquid is introduced from a washing liquid introduction portion provided in a washing tank located most downstream to a transport direction of a sample, moves counter-currently to the sample, and is discharged from a washing liquid outlet provided in a washing tank into which the sample firstly incorporated.

### (Washing Treatment 2)

The electrode was washed with ultra pure water in a washing apparatus with a single tank. Transporting distance in the tank was 10 m, and the electrode was discharged from the tank at a rate of 1 m/min. The flow rate of the washing liquid was 1 l/min. Thus, an electrode, which was washed in the washing apparatus with a single tank, was obtained. In the washing apparatus with a single tank above, a washing liquid is introduced from a washing liquid introduction portion provided at the bottom of the washing tank and discharged from a washing liquid outlet provided at the upper portion of the washing tank. A sample is transported according to a belt transferring method and introduced in the washing tank.

The resulting Organic EL Element samples 201 through 209 were evaluated for driving voltage stability, storage stability and lifetime in the same manner as in Example 1 above.

The results are shown in Table 2.

TABLE 2

| | | Water | | | | |
|---|---|---|---|---|---|---|
| | | amount | | | | |
| | | supplied | Driving | | | |
| | Washing | (Washing | Voltage | Storage | Life- | |
| Samples | Treatment | Method) | Stability | Stability | time | Remarks |
| 201 | 1 | 50 ml/min | 5 | 5 | 4 | Inventive |
| 202 | 1 | (Multi- | 5 | 5 | 4 | Inventive |
| 203 | 1 | stage | 5 | 5 | 4 | Inventive. |
| 204 | 1 | Washing) | 5 | 5 | 5 | Inventive. |
| 205 | 2 | 1 l/min | 5 | 5 | 4 | Inventive |
| 206 | 2 | (Single | 5 | 5 | 4 | Inventive |
| 207 | 2 | Tank | 5 | 5 | 4 | Inventive |
| 208 | 2 | Washing) | 5 | 5 | 5 | Inventive |
| 209 | None | None | 3 | 3 | 2 | Comparative |

As is apparent from Table 2, the inventive Organic EL Element Samples excel in prevention of short-circuiting between electrodes, driving voltage stability, storage stability and lifetime. Further, it has proved that in spite of less washing water, Organic EL Element Samples 201, 202, 203 and 204, which were subjected to multistage washing treatment, exhibit superior results as compared with Organic EL Element Samples 205, 206, 207 and 208, which were subjected to the single tank washing treatment.

### EXPLANATION OF SYMBOLS

10 Substrate
11 First Electrode
12 Second Electrode
13 Organic Functional Layer
14 Another Electrically Conductive Layer
21 Electrically Conductive Polymer-Containing Layer
22 Auxiliary Electrode (Metal Wire)
23 Auxiliary Electrode (Metal Grid)
A-1 ITO Electrode
A-2 Electrically Conductive Polymer-Containing Layer/Hole Transporting Layer/Light Emission Layer/Electron Transporting Layer
A-3 Cathode Electrode
A-4 Sealing Member
A-5 ITO Taken-out Electrode
A-6 Auxiliary Electrode

1. An organic electronic device comprising a substrate and provided thereon, a first electrode and a second electrode opposed to each other and at least one organic functional layer located between the first and second electrodes, wherein at least one of the first and second electrodes comprises an electrically conductive polymer-containing layer containing a hydrophilic polymer binder and an electrically conductive polymer comprised of a π conjugated electrically conductive polymer component and a polyanion component, at least a part of the electrically conductive polymer-containing layer is subjected to cross-linking, and the electrically conductive polymer-containing layer has been subjected to wet washing treatment.

2. The organic electronic device as described in claim 1, wherein the wet washing treatment is washing treatment carried out employing water or an aqueous solvent.

3. The organic electronic device as described in claim 1, wherein the wet washing treatment is a multi-stage washing treatment carried out employing two or more washing tanks which are continuously connected and charged with water or an aqueous solvent.

4. The organic electronic device as described in claim 3, wherein the wet washing treatment is a multi-stage washing treatment in which the water or the aqueous solvent overflows from a first tank to an adjacent second tank.

5. The organic electronic device as described in claim 1, wherein a carbon atom concentration at a surface of the electrically conductive polymer-containing layer after the wet washing treatment is not less than 3% higher than that before the wet washing treatment.

6. The organic electronic device as described in claim 1, wherein the polyanion component has a sulfo group, and the hydrophilic polymer binder has a hydroxyl group in the side chain.

7. (canceled)

8. (canceled)

9. The organic electronic device as described in claim 6, wherein the hydrophilic polymer binder comprises Polymer (A) containing at least one selected from the monomer units represented by the following (a1), (a2) and (a3), 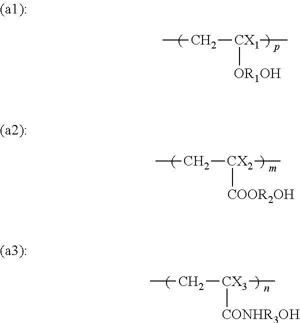
wherein X₁ through X₃ independently represent a hydrogen atom or a methyl group; R₁ through R₃ independently represent an alkylene group having a carbon atom number of not more than 5; and p, m and n represent a constitution ratio (by mol %), in which 50≦p+m+n≦100.

10. The organic electronic device as described in claim 9, wherein the cross-linking of the electrically conductive polymer-containing layer is carried out through dehydration reaction under elimination of the hydroxyl group.
